(19) United States
(12) Patent Application Publication
(10) Pub. No.: US 2019/0273038 A1
(43) Pub. Date: Sep. 5, 2019

(54) THROUGH-HOLE ELECTRODE SUBSTRATE, SEMICONDUCTOR DEVICE USING THE THROUGH-HOLE ELECTRODE SUBSTRATE AND MANUFACTURING METHOD OF THE THROUGH-HOLE ELECTRODE SUBSTRATE

(71) Applicant: DAI NIPPON PRINTING CO., LTD., Tokyo (JP)

(72) Inventors: Hiromasa NAGANO, Tokyo (JP); Takahiro TAI, Tokyo (JP); Shinji MAEKAWA, Tokyo (JP)

(73) Assignee: DAI NIPPON PRINTING CO., LTD., Tokyo (JP)

(21) Appl. No.: 16/414,809

(22) Filed: May 17, 2019

Related U.S. Application Data
(63) Continuation of application No. PCT/JP2017/037220, filed on Oct. 13, 2017.

(30) Foreign Application Priority Data
Nov. 17, 2016 (JP) 2016-223897

(51) Int. Cl. H01L 23/498; H05K 3/42; H05K 1/11; H01L 23/538; H01L 21/768

(52) U.S. Cl. CPC H01L 23/49822; H05K 3/429; H01L 21/76871; H01L 23/49811; H01L 23/5383; H05K 1/116

(57) ABSTRACT

A through-hole electrode substrate including substrate having a first and second surface on an opposite side of first surface and through-hole passing through from first surface to second surface, inner wall of through-hole divided into first inner wall, second inner wall and third inner wall from first surface side, size of a first open end of through-hole in first surface side is smaller than a size of a second open end of the through-hole in the second surface side, an incline angle with respect to first and second surface of the third inner wall is smaller than an incline angle with respect to the first surface and the second surface of the second inner wall and the third inner wall, and a through-hole electrode arranged on the interior of the through-hole and electrically connecting wiring arranged on the first surface side and wiring arranged on the second surface side.

### CROSS REFERENCE TO RELATED APPLICATIONS

This application is a U.S. continuation application filed below 35 U.S.C. § 111(a), of International Application No. PCT/JP2017/037220, filed on Oct. 13, 2017, which claims priority to Japanese Patent Application No. 2016-223897 filed on Nov. 17, 2016, the disclosures of which are incorporated by reference.

### FIELD

The present disclosure is related to a through-hole electrode substrate, a semiconductor device using the through-hole electrode substrate and a manufacturing method of the through-hole electrode substrate. One embodiment of the disclosure is related to a shape of a through-hole formed in a through-hole electrode substrate.

### BACKGROUND

In recent years, integrated circuits are becoming finer and more complex with the increase in performance of integrated circuits. A connection terminal is arranged in the integrated circuit, and a power supply and a logic signal which are necessary for circuit operations are input from an external device (chip) via the connection terminal. However, connection terminals on integrated circuits are arranged at a very narrow pitch due to miniaturization and complexity of integrated circuits. The pitch of a connection terminal on an integrated circuit is several to several tens times smaller than the pitch of connection terminals of a chip.

As described above, in the case where an integrated circuit and a chip which have connection terminals with different pitches are connected together, an interposer is used which serves as an intermediate substrate for converting a pitch interval of the connection terminals. In the interposer, an integrated circuit is mounted on wiring which is arranged on one side of a substrate and a chip is mounted on wiring which is arranged on the other side of the substrate. The pairs of wirings which are arranged on both sides of the substrate are connected to each other via a through-hole electrode which passes through the substrate.

TSV (Through-Silicon Via) which is a through-hole electrode substrate using a silicon substrate, and TGV (Through-Glass Via) which is a through-hole electrode substrate using a glass substrate, have been developed as interposers (for example, Japanese Laid Open Patent Publication 2014-223640, Japanese Laid Open Patent Publication 2014-240084, and Japanese Laid Open Patent Publication 2015-051897). In particular, since TGV can be manufactured using a large glass substrate with a vertical/horizontal size of 730 mm/920 mm for example, which is called a 4.5 generation, it is advantageous in that it is possible to reduce manufacturing costs. TGV has an advantage that it is possible to achieve development for parts which utilize transparency which is a characteristic of a glass substrate.

Coverage (or deposition property of a thin film) of a through-hole electrode inside a through-hole is very important in the interposer. When the coverage of the through-hole electrode is poor, it is no longer possible to secure an electrical connection between pairs of wires arranged on both sides of the substrate described above. Even in the case when the electrical connection between the pairs of wires is hardly secured, the through-hole electrode may be formed only in a region of a part of the through-hole inner wall. In the case when a current is supplied to the through-hole electrode, since the current becomes concentrated on the through-hole electrode which is formed in a region of a part of the inner wall of the through-hole, problems occur such as breakage of the through-hole electrode due to excessive self-heat generation. A cross-sectional shape of the through-hole which is formed in the substrate is very important in order to avoid this problem.

Furthermore, in the interposer, adhesion of the through-hole electrode to an inner wall of a through-hole is also very important. When the adhesion of the through-hole electrode to the through-hole inner wall is weak, the through-hole electrode may peel from the through-hole and no longer function as an interposer. In addition, the cross-sectional shape of the through-hole formed in a substrate is very important in order to avoid this problem.

### SUMMARY

A through-hole electrode substrate related to one embodiment of the present disclosure includes a substrate having a first surface, a second surface on an opposite side of the first surface and a through-hole passing through from the first surface to the second surface, an inner wall of the through-hole divided into a first inner wall, a second inner wall and a third inner wall from the first surface side, a size of a first open end of the through-hole in the first surface side is smaller than a size of a second open end of the through-hole in the second surface side, an incline angle with respect to the first surface and the second surface of the third inner wall is smaller than an incline angle with respect to the first surface and the second surface of the second inner wall and the third inner wall, and a through-hole electrode arranged on the interior of the through-hole and electrically connecting wiring arranged on the first surface side and wiring arranged on the second surface side.

A surface shape of the first inner wall may be a granular patterned uneven shape.

A surface shape of the second inner wall may be a linear patterned uneven shape extending in a direction intersecting the first surface and the second surface.

A surface shape of the second inner wall may be a granular patterned uneven shape, and a granular shape of the granular patterned uneven shape of the second inner wall extending in a direction intersecting the first surface and the second surface than a granular shape of the granular patterned uneven shape of the first inner wall.

A surface shape of the second inner wall may be a linear patterned uneven shape extending in a direction intersecting the first surface and the second surface.

A surface shape of the second inner wall may be a granular patterned uneven shape, and a granular shape of the granular patterned uneven shape of the second inner wall extending in a direction intersecting the first surface and the second surface than a granular shape of the granular patterned uneven shape of the first inner wall.

A surface shape of the first inner wall may be an uneven shape, and a surface shape of the second inner wall may be an uneven shape different to the uneven shape of the first inner wall and extending in a direction intersecting the first surface and the second surface.

A projection part may be included on the second surface in the vicinity of the second open end, the projection part projecting from the second surface in a direction opposite to the first surface.

The projection part may consecutively surround the second open end in a planar view.

The through-hole electrode may fill the interior of the through-hole.

The through-hole electrode may be arranged on the first inner wall, the second inner wall and the third inner wall, and a gap may be arranged further to the inner side than the through-hole electrode with respect to the through-hole.

A filler material arranged in the gap may be further arranged.

A semiconductor device related to one embodiment of the present disclosure may include a through-hole electrode substrate, an LSI substrate connected to the through-hole electrode of the substrate, and a semiconductor chip connected to the through-hole electrode of the substrate.

A manufacturing method of a through-hole electrode substrate related to one embodiment of the present disclosure may include using a substrate having a first surface, a second surface on an opposite side of the first surface and a through-hole passing through from the first surface to the second surface comprising, forming a seed layer in the first surface side, forming a first plating layer on the seed layer and covering the first open end, and forming a second plating layer on the first plating layer from the first surface side towards the second surface side, wherein a size of a first open end of the through-hole in the first surface side is smaller than a size of a second open end of the through-hole in the second surface side.

### BRIEF DESCRIPTION OF DRAWINGS

FIG. 1 is a cross-sectional diagram of a through-hole arranged in a substrate related to one embodiment of the present disclosure;

FIG. 2 is a cross-sectional diagram showing a process for attaching a film to a substrate mounted on a stage in a manufacturing method of a substrate related to one embodiment of the present disclosure;

FIG. 3 is a cross-sectional diagram showing a process for irradiating laser light on a substrate related to one embodiment of the present disclosure;

FIG. 4 is a cross-sectional diagram for explaining an altered layer formed by laser irradiation in a manufacturing method of a substrate related to one embodiment of the present disclosure;

FIG. 5 is a cross-sectional diagram showing a process for peeling a film from a substrate in a manufacturing method of a substrate related to one embodiment of the present disclosure;

FIG. 6 is a cross-sectional diagram showing a process for selectively etching an altered layer formed on a substrate in a manufacturing method of a substrate related to one embodiment of the present disclosure;

FIG. 7 is a cross-sectional diagram showing a state in which a through-hole is formed in a substrate in a manufacturing method of a substrate related to one embodiment of the present disclosure;

FIG. 8 is a cross-sectional diagram of a through-hole arranged in a substrate related to one embodiment of the present disclosure;

FIG. 9 is a top view diagram of a through-hole arranged in a substrate related to one embodiment of the present disclosure;

FIG. 10 is a cross-sectional SEM image of a through-hole formed in a substrate by a manufacturing method of a substrate related to one embodiment of the present disclosure;

FIG. 11 is an enlarged cross-sectional SEM image of a region A in FIG. 10;

FIG. 12 is an enlarged cross-sectional SEM image of a region B in FIG. 10;

FIG. 13 is an enlarged cross-sectional SEM image of a region C in FIG. 10;

FIG. 14 is a perspective SEM image of a sample in FIG. 13 observed diagonally from above;

FIG. 15 is a cross-sectional diagram showing a process for irradiating laser light on a substrate in a manufacturing method of a substrate related to one embodiment of the present disclosure;

FIG. 16 is a cross-sectional diagram for explaining a concave part formed by laser irradiation in a manufacturing method of a substrate related to one embodiment of the present disclosure;

FIG. 17 is a cross-sectional diagram showing a process for peeling a film from a substrate in a manufacturing method of a substrate related to one embodiment of the present disclosure;

FIG. 18 is a cross-sectional diagram showing a process for etching a concave part of substrate and a damage layer in a manufacturing method of a substrate related to one embodiment of the present disclosure;

FIG. 19 is a cross-sectional diagram of a through-hole electrode substrate related to one embodiment of the present disclosure;

FIG. 20 is a cross-sectional diagram showing a process for forming a seed layer on a first surface side in a manufacturing method of a through-hole electrode substrate related to one embodiment of the present disclosure;

FIG. 21 is a cross-sectional diagram showing a process for forming a plating layer which covers an open part of a first surface side in a manufacturing method of a through-hole electrode substrate related to one embodiment of the present disclosure;

FIG. 22 is a cross-sectional diagram showing a process for growing a plating layer from a first surface side towards a second surface side in a manufacturing method of a through-hole electrode substrate related to one embodiment of the present disclosure;

FIG. 23 is a cross-sectional diagram showing a process for filling the interior of a through-hole with a through-hole electrode in a manufacturing method of a through-hole electrode substrate related to one embodiment of the present disclosure;

FIG. 24 is a cross-sectional diagram showing a process for polishing a seed layer and a plating layer formed on a first surface side and a playing layer formed on a second surface side in a manufacturing method of a through-hole electrode substrate related to one embodiment of the present disclosure;

FIG. 25 is a cross-sectional diagram of a through-hole electrode substrate related to one embodiment of the present disclosure;

FIG. 26 is a cross-sectional diagram of a through-hole electrode substrate related to one embodiment of the present disclosure;

FIG. 27 is a cross-sectional diagram showing a semiconductor device using a through-hole electrode substrate related to one embodiment of the present disclosure;

FIG. 28 is a cross-sectional diagram showing another example of a semiconductor device using a through-hole electrode substrate related to one embodiment of the present disclosure;

FIG. 29 is a cross-sectional diagram showing yet another example of a semiconductor device using a through-hole electrode substrate related to one embodiment of the present disclosure;

FIG. 30A is a cross-sectional diagram showing an example of an electronic device using a through-hole electrode substrate related to one embodiment of the present disclosure as an interposer;

FIG. 30B is a cross-sectional diagram showing an example of an electronic device using a through-hole electrode substrate related to one embodiment of the present disclosure as an interposer;

FIG. 30C is a cross-sectional diagram showing an example of an electronic device using a through-hole electrode substrate related to one embodiment of the present disclosure as an interposer;

FIG. 30D is a cross-sectional diagram showing an example of an electronic device using a through-hole electrode substrate related to one embodiment of the present disclosure as an interposer;

FIG. 30E is a cross-sectional diagram showing an example of an electronic device using a through-hole electrode substrate related to one embodiment of the present disclosure as an interposer; and

FIG. 30F is a cross-sectional diagram showing an example of an electronic device using a through-hole electrode substrate related to one embodiment of the present disclosure as an interposer.

### DESCRIPTION OF EMBODIMENTS

A through-hole electrode substrate, a semiconductor device using the through-hole electrode substrate and a manufacturing method of the through-hole electrode substrate are explained in detail below while referring to the drawings. The embodiments shown below are one example of an embodiment of the present disclosure. That is, the disclosure should not to be interpreted as being limited to these embodiments. In the drawings referenced in the present embodiment, letters of the alphabet are attached after the same symbols to the same elements or elements having the same function and a repeated explanation may be omitted accordingly. The dimension ratios of the drawings may be different to actual ratios for the purposes of explanation and structural parts of may be omitted from the drawings.

In each embodiment of the present disclosure, the side of a first surface 102 of a substrate 100 is referred to as under or below the substrate 100. Reversely, the side of a second surface 104 of the substrate 100 is referred to as on or above the substrate 100. In this way, although the terms above and below are used for the purposes of explanation, for example, the vertical relationship between the first surface 102 and second surface 104 may be arranged so as to be the reverse of that exemplified in the drawings. In the explanation herein, expressions such as first stacked wiring 300 above the substrate 100 is merely explaining the vertical relationship between the substrate 100 and the first stacked wiring 300 as described above, and other members may also be arranged between the substrate 100 and the first stacked wiring 300.

The embodiments herein aim to provide a substrate with improved coverage of a through-hole electrode in a through-hole. Alternatively, it is an aim to provide a substrate in which peeling of a through-hole electrode from the through-hole can be suppressed.

### First Embodiment

### [Shape of Through-Hole 110]

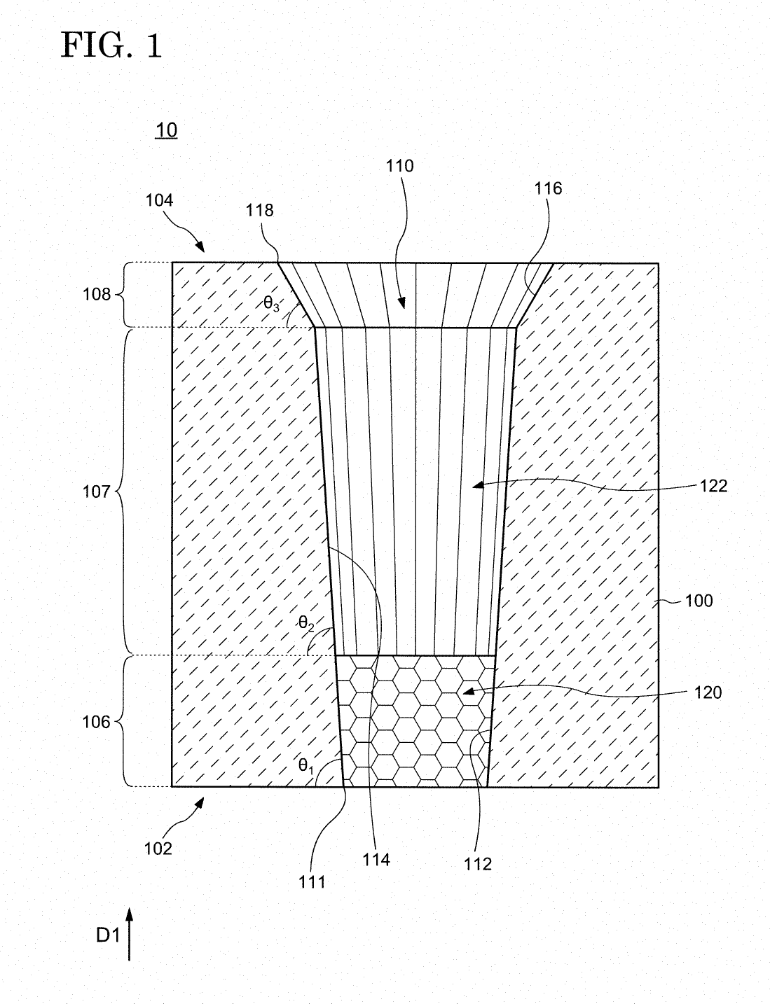

The shape of a through-hole 110 arranged in a substrate 100 which is used for a through-hole electrode substrate 10 related to the present embodiment is explained using FIG. 1 to FIG. 14. In FIG. 1 to FIG. 14, the through-hole electrode arranged inside the through-hole 110 is omitted for the convenience of explaining a cross-sectional shape of the through-hole 110 and the surface shape of an inner wall of the through-hole 110.

FIG. 1 is a cross-sectional diagram of a through-hole which is arranged in a substrate related to one embodiment of the present disclosure. As is shown in FIG. 1, a through-hole 110 which passes through a first surface 102 and a second surface 104 is arranged in the substrate 100. The second surface 104 is a surface on the opposite side to the first surface 102 with the substrate 100 as a reference. The through-hole 110 is divided into a first region 106, a second region 107 and a third region 108 from the first surface 102 side. An inner wall of the through-hole 110 is divided into a first inner wall 112, a second inner wall 114 and a third inner wall 116 from the first surface 102 side corresponding to the three regions described above. The size of a first open end 111 of the through-hole 110 on the first surface 102 side is smaller than the size of a second open end 118 of the through-hole 110 on the second surface 104 side.

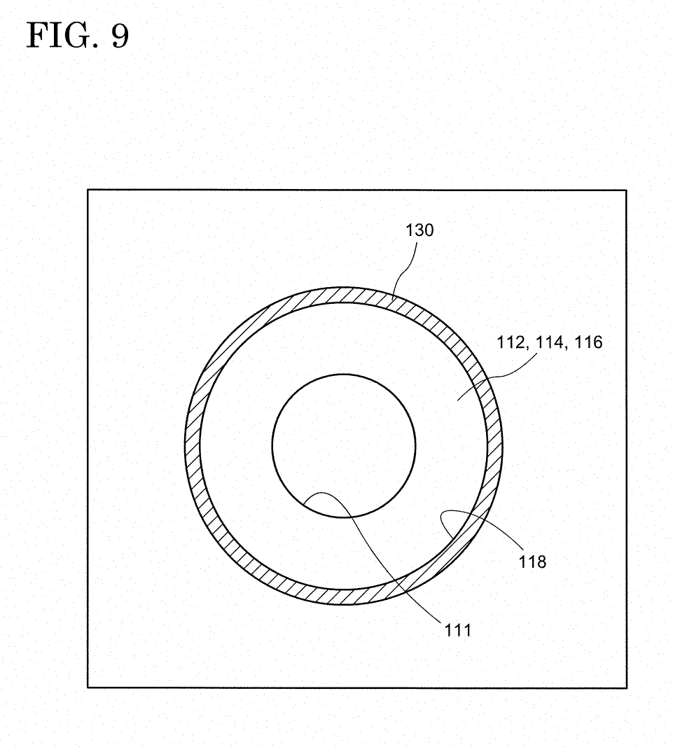

The cross-sectional diagram shown in FIG. 1 is a cross-sectional diagram in which the substrate 100 is cut so as to pass through the center of the through-hole 110 in a top surface view (FIG. 9) of the through-hole 110 described herein and the cut surface is observed from a side direction. That is, the size of the first open end 111 and the size of the second open end 118 mean a maximum width of the through-hole 110 in a top surface view of the through-hole 110. However, the surface shape of the inner wall of the through-hole 110 explained herein is not limited to the shape evaluated using the cut surface described above.

The surface of the inner wall of the through-hole 110 has an uneven shape. The uneven shape on the inner wall surface is visually recognized as a pattern which is different depending on the place. For example, the uneven shape of the surface of the first inner wall 112 is a granular pattern 120. The uneven shape of the surface of the second inner wall 114 is a linear pattern 122. In other words, the surface shape of the first inner wall 112 is an uneven shape of the granular pattern 120, and the surface shape of the second inner wall 114 is an uneven shape of the linear pattern 122. The extending direction of the linear shape of the linear pattern 122 is a direction (referred to below as “first direction D1”) intersecting with the first surface 102 and the second surface 104. The uneven shape of the surface of the third inner wall 116 continuously extends from the linear pattern 122 of the second inner wall 114 to the second surface 104. Although described in detail herein, in the first inner wall 112 and the second inner wall 114 in FIG. 1, a section of the first inner wall 112 represented by a line is a convex part, and a region surrounded by a line or a region sandwiched by a line is a concave part.

In FIG. 1, although the first direction D1 is a direction orthogonal to the first surface 102 and the second surface 104, the first direction D1 is not limited to this direction. For example, the first direction D1 may be a direction which is inclined with respect to a line orthogonal to the first surface 102 and the second surface 104. That is, in FIG. 1, although each line of the linear pattern 122 exemplifies a shape which is orthogonal to the first surface 102 and the second surface 104, the present invention is not limited to this shape. Each line of the linear pattern 122 may also be inclined with respect to a line which is orthogonal to the first surface 102 and the second surface 104.

In other words, the granular pattern 120 can also be called a scaly shaped pattern, a closed loop shape pattern or a ring shaped pattern. In other words, the linear pattern 122 can also be called a granular pattern which extends in the first direction D1 more than the granular pattern 120 of the first inner wall 112. In FIG. 1, although the granular pattern 120 has a shape in which each grain pattern is a hexagonal honeycomb pattern, the granular pattern 120 is not limited to this shape. Each grain pattern of the granular pattern 120 may be a circular shape, an oval shape, a polygonal shape or other curved shapes or a combination of these shapes.

When the space between adjacent grains of the granular pattern 120 is defined as a grain boundary, in the first inner wall 112, a straight line which extends in the first direction D1 intersects with a plurality of grain boundaries in a cross-sectional view of the through-hole 110. On the other hand, in the second inner wall 114, the straight line described above does not intersect with a plurality of grain boundaries. A plurality of grain patterns exist in the first direction D1 in the first inner wall 112. On the other hand, one grain pattern having a longitudinal direction in the first direction D1 exists in the second inner wall 114. The second inner wall 114 is longer than the first inner wall 112 in the first direction D1. The grain boundaries which are defined as described above correspond to the convex parts of the inner wall.

The granular pattern 120 is formed on the first inner wall 112 so as to enclose the through-hole 110 in a top surface view. In other words, the first region 106 is a region which is enclosed by the first inner wall 112 of the granular pattern 120. The linear pattern 122 is formed on the second inner wall 114 so as to enclose the through-hole 110 in a top surface view. In other words, the second region 107 is a region which is enclosed by the second inner wall 114 of the linear pattern 122.

The third inner wall 116 is inclined in a direction in which the size of the through-hole 110 becomes larger compared to the first inner wall 112 and the second inner wall 114. That is, an inclination angle θ₃ of the third inner wall 116 with respect to a surface which is parallel to the first surface 102 and the second surface 104 is smaller than the inclination angles θ₁ and θ₂ of the first inner wall 112 and the second inner wall 114 with respect to the first surface 102 and the second surface 104. Although a structure is shown in FIG. 1 in which the first inner wall 112, the second inner wall 114 and the third inner wall 116 have a linear shape in a cross-sectional view, the present invention is not limited to this structure. As is explained in detail herein, the cross-sectional shape of the inner wall of the through-hole 110 which is actually formed is often not a straight line. In this type of case, on each of the inner walls of the first inner wall 112, the second inner wall 114 and the third inner wall 116, it is possible to set each inclination angle θ₁ to θ₃ with respect to the first surface 102 and the second surface 104 of a line part which connects two different points which are sufficiently separated in the first direction D1.

Although the cross-sectional diagram shown in FIG. 1 is a cut surface passing through the center of the through-hole 110 in a top surface view, the size relationship of the inclination angles θ₁ to θ₃ described above does not change if the evaluation is on the same cut surface. Therefore, the size relationship of the inclination angles can be evaluated using an arbitrary cut surface.

As described above, according to the substrate 100 of the through-hole electrode substrate 10 related to the first embodiment, the inclination angle of the third inner wall 116 inclines in a direction in which the size of the through-hole 110 increases compared to the inclination angle of each of the first inner wall 112 and the second inner wall 114, and thereby a through-hole electrode is formed inside the through-hole 110 with good coverage. According to the substrate 100 related to the first embodiment, since the uneven shape of the granular pattern 120 is formed on the first inner wall 112, when the through-hole electrode arranged inside the through-hole 110 receives an action in a direction in which the through-hole electrode is pulled out in the first direction D1, the movement of the through-hole electrode in the first direction D1 is blocked by the uneven shape of the first inner wall 112. As a result, even when the through-hole electrode arranged inside the through-hole 110 receives an external force in the first direction D1, the through-hole electrode is suppressed from being detached from the through-hole 110. According to the substrate 100 related to the first embodiment, since the uneven shape of the linear pattern 122 is formed on the second inner wall 114, even in the case where the through-hole electrode arranged inside the through-hole 110 receives an external force in a direction of rotation with a line extending in the first direction D1 of the through hole 110 as a central axis, misalignment of the through-hole electrode in the rotational direction described above is blocked by the uneven shape of the second inner wall 114. As a result, it is possible to suppress detachment of the through-hole electrode arranged in the through-hole 110 from the through-hole 110.

### [Formation Method of Through-Hole 110]

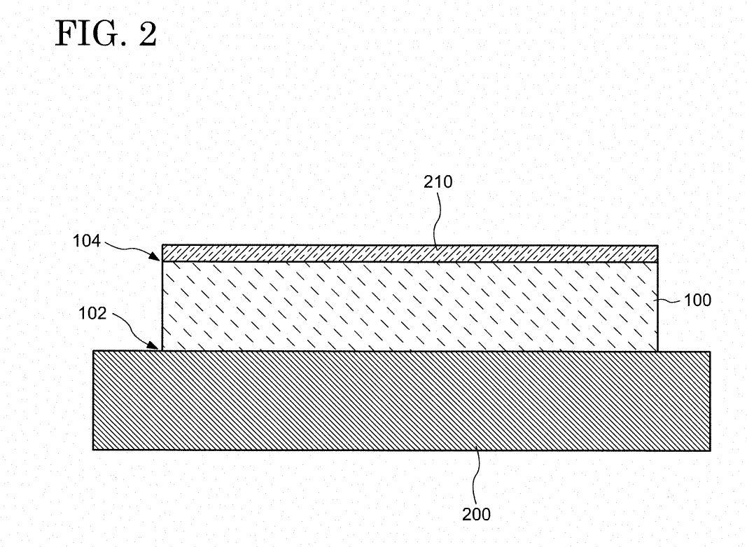

A formation method of the through-hole 110 arranged in the substrate 100 which is used in the through-hole electrode substrate 10 is explained using FIG. 2 to FIG. 7. Here, a method of forming the through-hole 110 in the substrate 100 using glass is explained.

FIG. 2 is a cross-sectional diagram showing a process for attaching a film to a substrate which is placed on a stage in a method of manufacturing a substrate related to one embodiment of the present disclosure. As is shown in FIG. 2, a protective film 210 is attached to the second surface 104 side of the substrate 100, and the first surface 102 side of the substrate 100 is placed on a processing stage 200. The protective film 210 includes a resin layer and a pressure-sensitive adhesive layer.

For example, it is possible to use polyethylene terephthalate (PET) as the resin layer of the protective film 210. However, the resin layer is not limited to material described above and other resin materials may be used. The thickness of the protective film 210 can be set, for example, to 10 μm or more and 150 μm or less. However, the thickness of the protective film 210 may also be a thickness other than the range described above.

The protective film 210 is attached with the aim of suppressing adhesion of foreign objects to the second surface 104 of the substrate 100 when laser irradiation is performed in a subsequent step. The protective film 210 is attached to the substrate 100 via the pressure-sensitive adhesive layer. The pressure-sensitive adhesive layer has a feature whereby the adhesive strength changes by a predetermined treatment. For example, the pressure-sensitive adhesive layer may have a property in which the adhesion is reduced by ultraviolet irradiation. Alternatively, the pressure-sensitive adhesive layer may have a property in which the adhesion is reduced by wetting. The pressure-sensitive adhesive layer may have, for example, an adhesive strength of 3N/20 mm or more and 30N/20 mm or less before the treatment described above is performed. The pressure-sensitive adhesive layer may have, for example, an adhesive strength of 0.01 N/20 mm or more and 0.3N/20 mm or less after the treatment described above is performed. Furthermore, the adhesive force described above is a value evaluated by a 180 degree peeling test based on JIS Z0237. In other words, the property of the pressure-sensitive adhesive layer described above, the adhesive strength of the pressure-sensitive adhesive layer can be changed by, for example, 100 times or more and 1000 times or less before and after performing the treatment described above. For example, it is possible to use a dicing tape manufactured by Denka Co., Ltd. as the pressure-sensitive adhesive layer described above. However, methods other than dicing tape may also be used as the pressure-sensitive adhesive layer.

A pressure-sensitive adhesive layer may be arranged not only between the substrate 100 and the protective film 210 but also between the substrate 100 and the processing stage 200. It is possible to use an acrylic pressure-sensitive adhesive layer in which the adhesive strength does not change as the pressure-sensitive adhesive layer which is arranged between the substrate 100 and the processing stage 200. For example, it is possible to use a fine pressure-sensitive adhesive tape manufactured by Lintec Co., Ltd. as the pressure-sensitive adhesive layer. However, layers other than the fine pressure-sensitive adhesive tape may also be used as the pressure-sensitive adhesive layer. The adhesion strength of the fine pressure-sensitive adhesive tape described above is, for example, 0.3N/30 mm.

An alumite treated is performed on the surface of the processing stage 200. However, the surface of the processing stage 200 does not need to be alumited, and the material itself of the processing stage 200 may be exposed. The processing stage 200 supports the substrate 100 using suction.

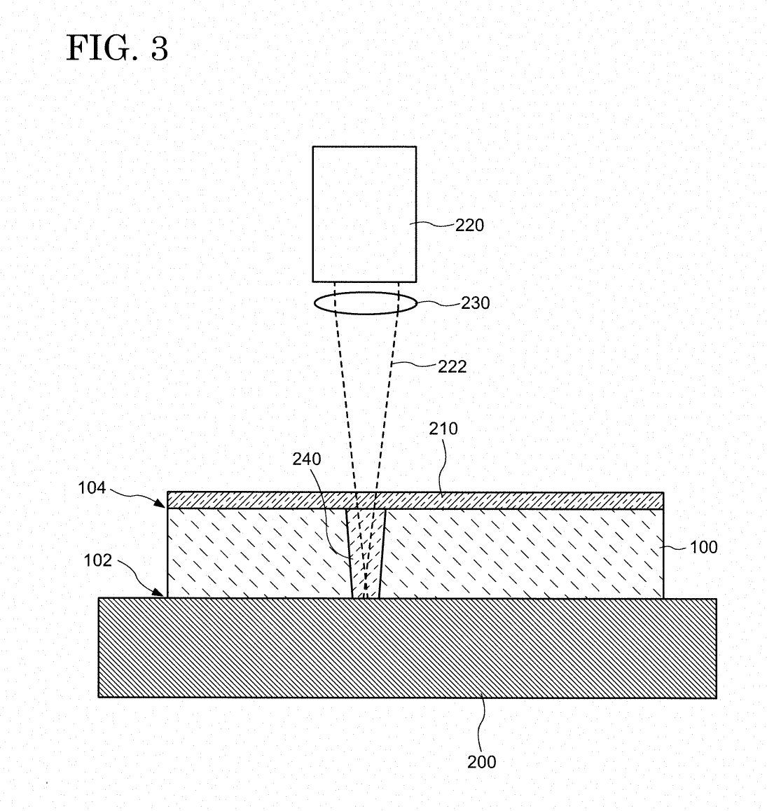

FIG. 3 is a cross-sectional diagram showing a step for irradiating a substrate with laser light in the method of manufacturing a substrate related to one embodiment of the present disclosure. By irradiating the substrate 100 with a laser from the protective film 210 side, an altered layer 240 is formed in a region where a through-hole 110 of the substrate 100 is formed. The laser light 222 which is emitted from a light source 220 is collected by a lens unit 230 and irradiated onto the substrate 100. The lens unit 230 is adjusted so that the laser light 222 is focused within the substrate 100. When the laser light 222 is irradiated onto the substrate 100, the altered layer 240 corresponding to the irradiation region of the laser light 222 and the intensity of the laser light 222 is formed.

An excimer laser, Nd: YAG laser (fundamental wave (wavelength: 1064 nm), second harmonic (wavelength: 532 nm), third harmonic (wavelength: 355 nm)), a CO₂ laser, and a femtosecond laser, etc are used as the laser light 222.

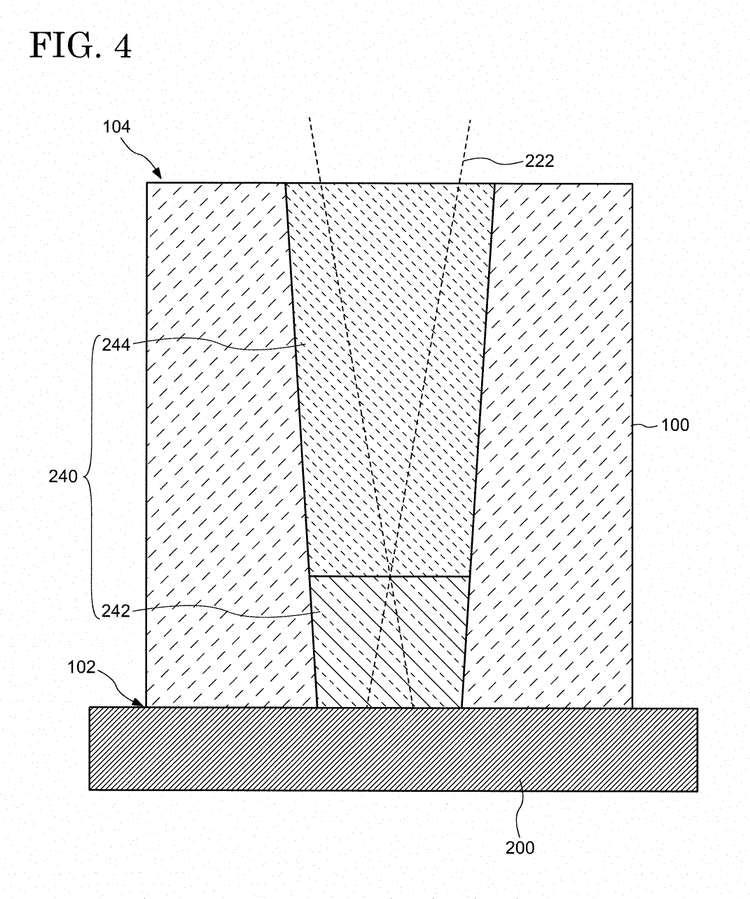

FIG. 4 is a cross-sectional diagram for explaining an altered layer formed by laser irradiation in the method for manufacturing a substrate related to one embodiment of the present disclosure. The positional relationship between the focal point of the laser light 222 and the substrate 100 and the positional relationship between the focal point of the laser light 222 and the altered layer 240 are explained using FIG. 4. As is shown in FIG. 4, the laser light 222 is focused within the substrate 100. In other words, the laser light 222 is focused between the first surface 102 and the second surface 104.

When the laser light 222 which is focused within the substrate 100 is irradiated onto the substrate 100, at least two different altered layers (first altered layer 242 and second altered layer 244) are formed within the substrate 100. In the case when the first altered layer 242 and the second altered layer 244 are not particularly distinguished, they are referred to simply as the altered layer 240. The first altered layer 242 is formed on the first surface 102 side. The second altered layer 244 is formed on the second surface 104 side. A boundary between the first altered layer 242 and the second altered layer 244 exists in the vicinity of the focal point of the laser light 222. The first altered layer 242 is a region where the substrate 100 is etched in a subsequent process and serves as the first region 106. The second altered layer 244 is a region where the substrate 100 is etched in a subsequent process and serves as the second region 107 and the third region 108. Although a structure is shown in FIG. 4 in which the boundary between the first altered layer 242 and the second altered layer 244 matches with the position of the focal point of the laser light 222, the present invention is not limited to this structure. The boundary between the first altered layer 242 and the second altered layer 244 may also be positioned closer to the first surface 102 side than the focal point of the laser beam 222, and located closer to the second surface 104 side than the focal point of the laser light 222. The laser light 222 which has passed through the substrate 100 is absorbed by the processing stage 200 on the first surface 102 side.

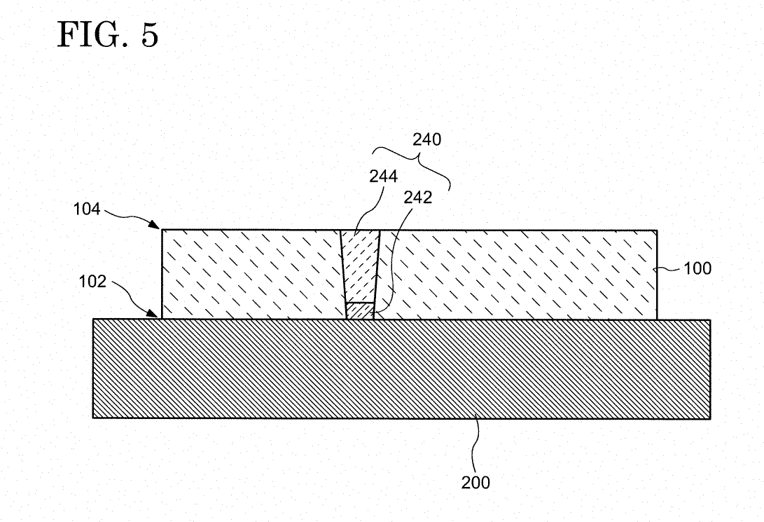

FIG. 5 is a cross-sectional diagram showing a process for peeling a film from a substrate in the method of manufacturing a substrate related to one embodiment of the present disclosure. The protective film 210 is peeled off from the substrate 100 after the altered layer 240 is formed on the substrate 100 by laser irradiation. The substrate 100 is washed after peeling off the protective film 210. Sulfuric acid/hydrogen peroxide cleaning (SPM), ammonia/hydrogen peroxide cleaning (APM), and ozone water or the like can be used for cleaning the substrate 100.

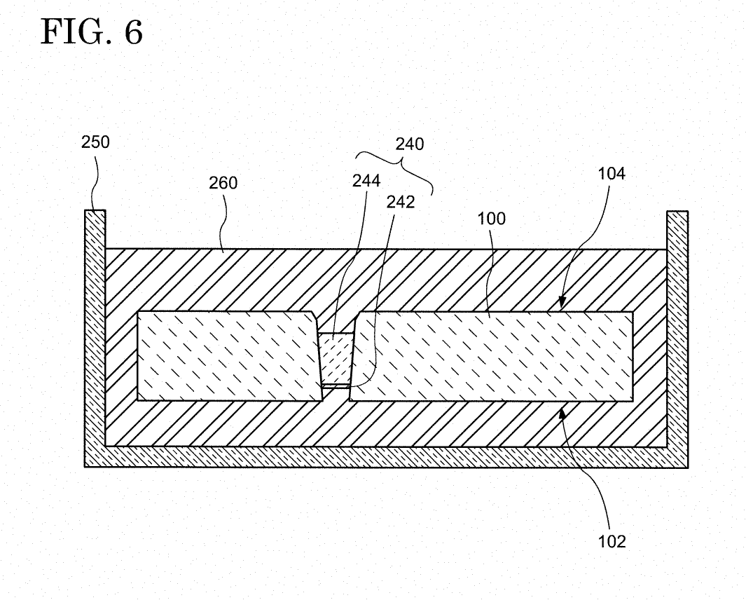

FIG. 6 is a cross-sectional diagram showing a process for selectively etching an altered layer formed on a substrate in the method of manufacturing a substrate related to one embodiment of the present disclosure. The first altered layer 242 and the second altered layer 244 have a faster etching rate with respect to a chemical solution compared to the substrate 100 in an unaltered region. That is, by simply immersing the substrate 100 in a chemical solution 260, the first altered layer 242 and the second altered layer 244 are selectively etched or etched at a faster speed than the substrate 100 in an unaltered region. Although an etching method is shown in FIG. 6 in which etching is performed from both sides of the first surface 102 side and the second surface 104 side by immersing the substrate 100 in the chemical solution 260 which is contained in a container 250, the present invention is not limited to this method. For example, etching may also be performed by from the second surface 104 side by applying a chemical solution from the second surface 104 side of the substrate.

If the substrate 100 is a glass substrate, hydrogen fluoride (HF), buffered hydrogen fluoride (BHF), and surfactant-added buffered hydrogen fluoride (LAL) or the like is used as the chemical solution 260 used for etching. Hydrogen sulfide (H₂SO₄), hydrogen nitrate (HNO₃), or hydrogen chloride (HCl) and the like is used as a chemical solution other than hydrogen fluoride. Alternatively, a chemical solution obtained by mixing the chemical solutions described above may also be used. It is possible to appropriately select the chemical solution used for the etching according to the material of the substrate. Other than the method for immersing the substrate 100 in the chemical solution 260 in the container 250, a spin coat etching method can be used as the etching method. In the case when spin coating type etching is performed, just one side may be etched, or one side at a time or both sides may be etched. Other than the spin coat etching method, a dip method or the like can be used as the etching method.

The first altered layer 242 and the second altered layer 244 are in different states. Therefore, the surface states of regions corresponding to the first altered layer 242 and the second altered layer 244 after etching are also different. Specifically, the surface state after etching the first altered layer 242 is a granular patterned uneven shape, and the surface state after etching the second altered layer 244 is a linear patterned uneven shape. That is, the first inner wall 112 of the granular pattern 120 is formed by etching the first altered layer 242, and the second inner wall 114 of the linear pattern 122 is formed by etching the second altered layer 244. Furthermore, the vicinity of the second surface 104 of the second altered layer 244 is etched in a direction in which the size of the through-hole 110 expands by the etching described above, and the third inner wall 116 is formed.

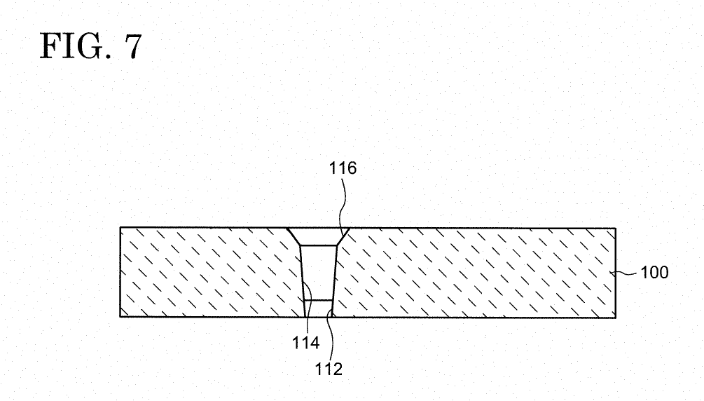

FIG. 7 is a cross-sectional diagram showing a state in which a through-hole is formed in a substrate in the method of manufacturing a substrate related to one embodiment of the present disclosure. The through-hole 110 formed by an inner wall including the first inner wall 112, the second inner wall 114 and the third inner wall 116 is formed in the substrate 100 with the manufacturing method explained using to FIGS. 2 to 6.

There is no particular limitation to the shape in planar view of the through-hole 110, for example, it may be circular or a rectangle or a polygon shape. Naturally, the corners may be rounded rectangles or polygon shaped.

In the explanation above, although a manufacturing method is exemplified in which the through-hole 110 is formed in the substrate 100 by forming an altered layer in the substrate 100 by laser irradiation and selectively etching the altered layer using a chemical solution, the present invention is not limited to this manufacturing method. For example, if it is possible to form the through-hole 110 including the characteristics explained using FIG. 1, the through-hole 110 may be formed by methods other than the manufacturing method described above. Specifically, the through-hole 110 may be formed by dry etching. The through-hole 110 may be formed using a reactive ion etching (RIE) method or a DRIE (deep reactive ion etching) method using a Bosch process as the dry etching. Alternatively, the through-hole 110 may be formed by a sandblasting method or laser ablation method. After the through-hole 110 is formed by the laser ablation method, the shape of the through-hole 110 may be adjusted by carrying out an electric discharge process on the interior of the formed through-hole 110. Alternatively, the through-hole 110 may be formed by combining the wet etching explained in the present embodiment and a processing method which includes the dry etching described above.

As described above, according to the method of manufacturing the substrate 100 of the through-hole electrode substrate 10 related to the first embodiment, by performing laser irradiation on the substrate 100 below the condition that the focal point of the laser light 222 is located on the interior of the substrate 100, it is possible to form a first inner wall 112, a second inner wall 114 and a third inner wall 116 which have different surface states. Furthermore, according to the manufacturing method described above, it is possible to form the third inner wall 116 having a different inclination angle from the first inner wall 112 and the second inner wall 114.

### Modified Example of First Embodiment

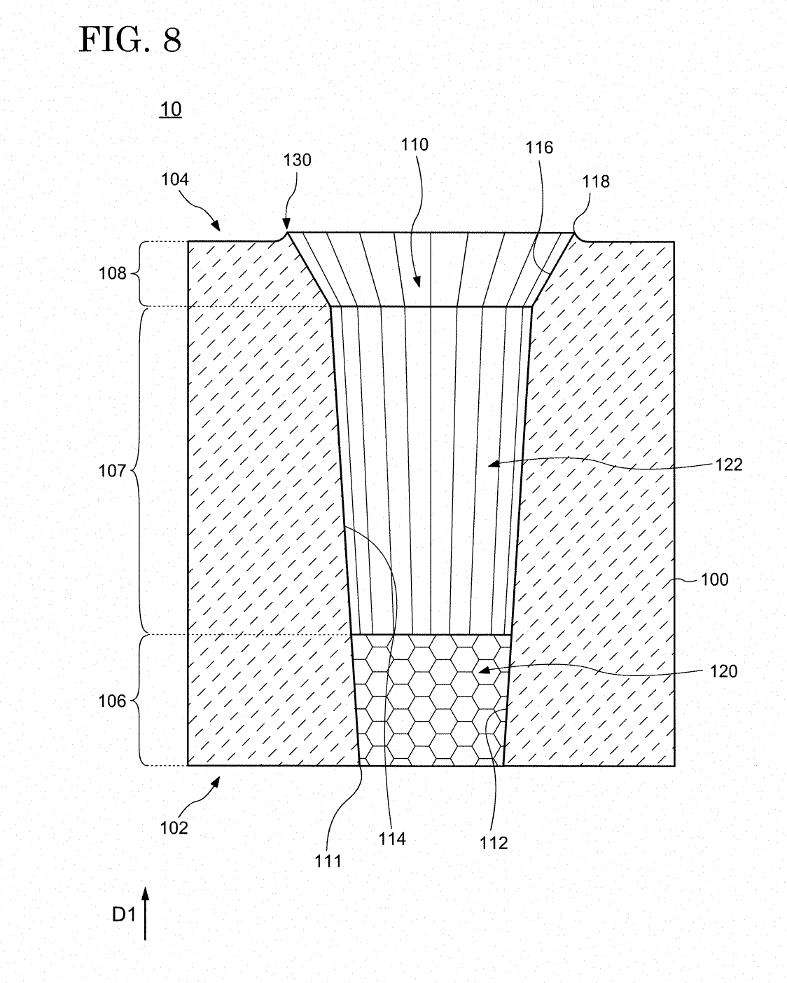

FIG. 8 is a cross-sectional diagram of a through-hole arranged in a substrate related to one embodiment of the present disclosure. When the through-hole 110 is formed by the laser irradiation explained using FIG. 3 and FIG. 4, as is shown in FIG. 8, a projection part 130 which projects from above the second surface 104 may be formed above the second surface 104 in the vicinity of the second open end 118 (an opposite direction to the second surface 104 with respect to the first surface 102). The substrate 100 which is shown in FIG. 1 is in a state in which the projection part 130 shown in FIG. 8 is removed. Chemical mechanical polishing (CMP) is used as a method for removing the projection 130 shown in FIG. 8. However, as is shown in FIG. 8, the through-hole electrode substrate 10 may be formed in a state in which the projection part 130 remains. FIG. 9 shows a top surface diagram of FIG. 8. As is shown in FIG. 9, the projection part 130 continuously encloses the second open end 118 in a planar view.

Similar to a conventional through-hole, in the case when a substrate surface in the vicinity of an open end of the through-hole has a flat shape without a projection part, when the through-hole electrode which projects further above the substrate surface from the through-hole is planarized by CMP, a concave shape called dishing may be formed at the boundary between the substrate and the through-hole electrode which have different polishing speeds with respect to CMP. When a concave shape is formed at the boundary between the substrate and the through-hole electrode, it is not possible for wiring which is formed thereon to cover the concave shape and may in some cases break. As is shown in FIG. 8, by arranging the projecting part 130, it is possible to suppress the occurrence of dishing even when polishing by CMP is performed.

### Example of First Embodiment

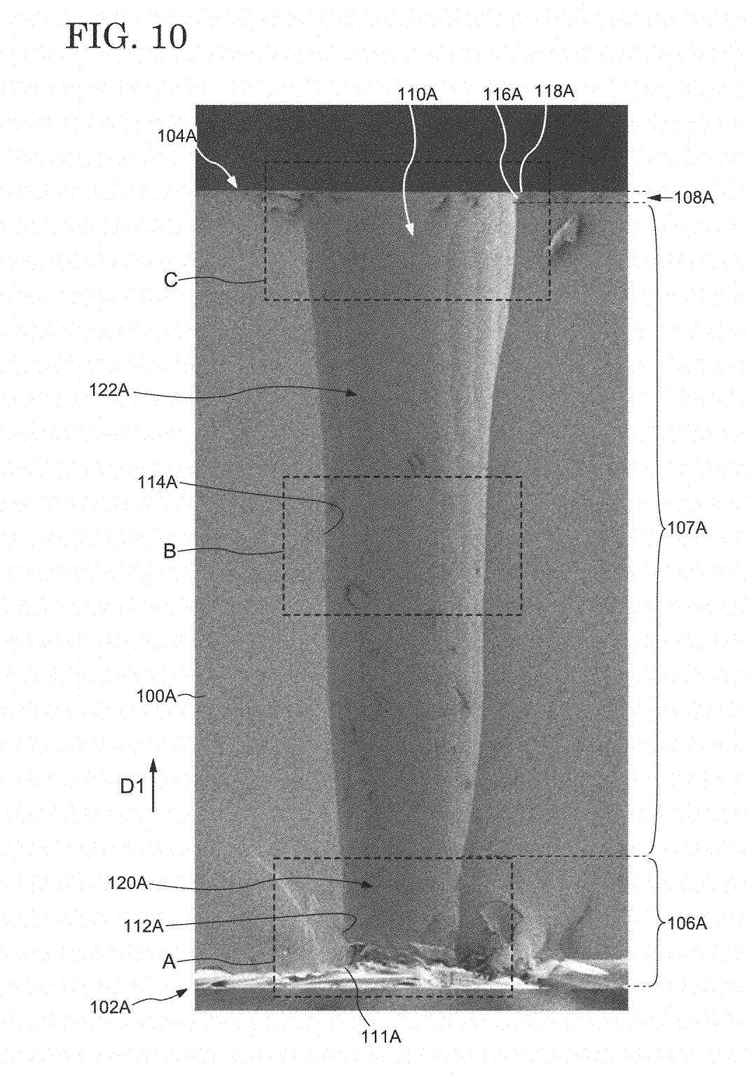

A through-hole 110A is formed in a substrate 100A using glass by the formation method described above and the results of observing a cross-sectional shape of the through-hole 110A are explained using FIG. 10 to FIG. 14. A sample used for observation in FIG. 10 to FIG. 14 is formed by laser irradiation below the condition that the focal point of the laser light is located further on the second surface 104 side than the center point between the first surface 102 and the second surface 104 using an Nd: YAG laser (third harmonic (wavelength: 355 nm)) as a laser light source.

FIG. 10 is a cross-sectional SEM (Scanning Electron Microscope) image of a through-hole formed by the manufacturing method of a substrate related to one embodiment of the present disclosure. The through-hole 110A which is formed in the substrate 100A shown in FIG. 10 is substantially circular in a planar view. The thickness of the substrate 100A is about 400 μm. The diameter of a first open end 111A is about 50 μm, and the diameter of a second open end 118A is about 85 μm. The length from the first surface 102A of a first region 106A, that is, the length in the first direction D1 of the first region 106A is about 100 μm. The length of a third region 108A from the second surface 104A, that is, the length in the first direction D1 of the third region 108A is about 20 μm. The length of the second region 107A in the first direction D1 is about 280 μm.

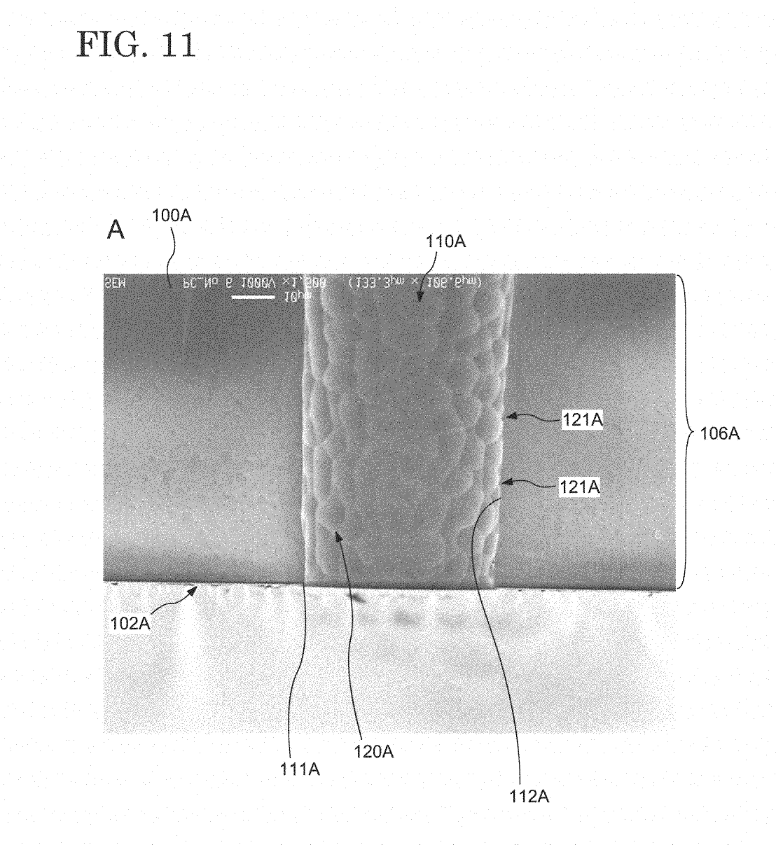

FIG. 11 is an enlarged cross-sectional SEM image of the region A in FIG. 10. As is shown in FIG. 11, the first inner wall 112A of the through-hole 110A in the first region 106A has a granular pattern 120A uneven shape. It is confirmed that a convex part 121A is the part between adjacent grain shapes (grain boundaries) of the granular pattern 120A. In the cross-sectional SEM image shown in FIG. 11, although the granular pattern 120A appears sharper in the region close to the first inner wall 112A, this is because of a cross-sectional observation of the sample shape and an SEM observation, and the actual size of the uneven shape of the first inner wall 112A is about the same in a circumferential direction of the through-hole 110A.

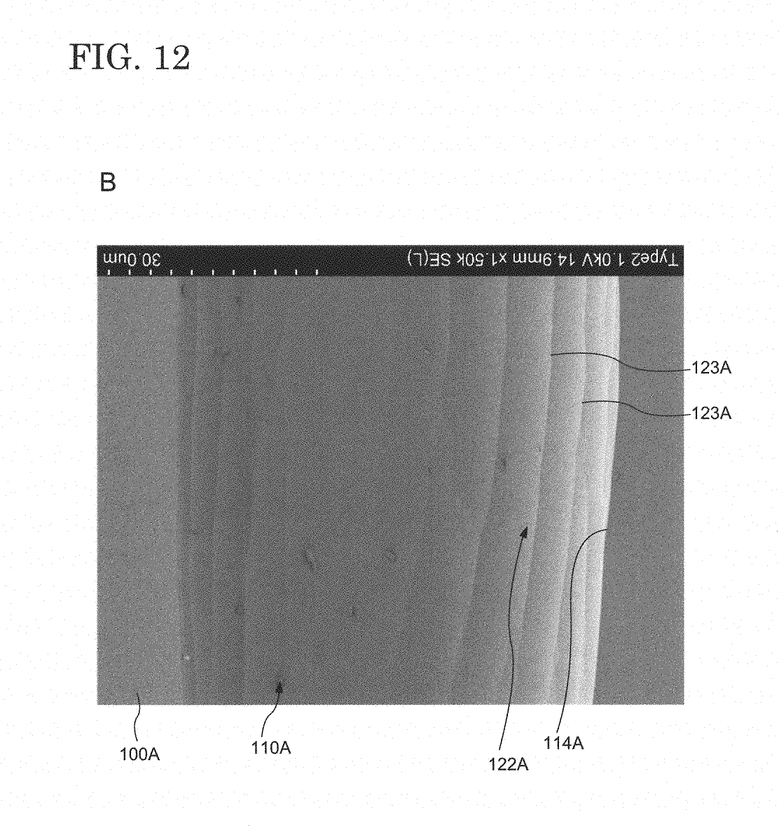

FIG. 12 is a cross-sectional SEM image of an enlarged region B in FIG. 10. As is shown in FIG. 12, the second inner wall 114A of the through-hole 110A in the second region 107A has a linear patterned 122A uneven shape. Although the details are described later, it has been confirmed that the line part of the linear pattern 122A is the convex part 123A. In the cross-sectional SEM image shown in FIG. 12, although the linear pattern 122A appears vivid in the region closer to the second inner wall 114A, the size of the undulation of the uneven shape of the second inner wall 114A is actually substantially the same applies in a circumferential direction of the through-hole 110A as described above. However, as is shown in FIG. 12, the linear pattern 122A may not have a linear shape as is shown in FIG. 1. Although the direction in which the lines of the linear pattern 122A extend may be a direction which is orthogonal to the first surface 102A and the second surface 104A, the direction may also be an incline direction with respect to the orthogonal direction. In either case, the direction in which the linear shape of the linear pattern 122A extends is a direction which intersecting the first surface 102A and the second surface 104A.

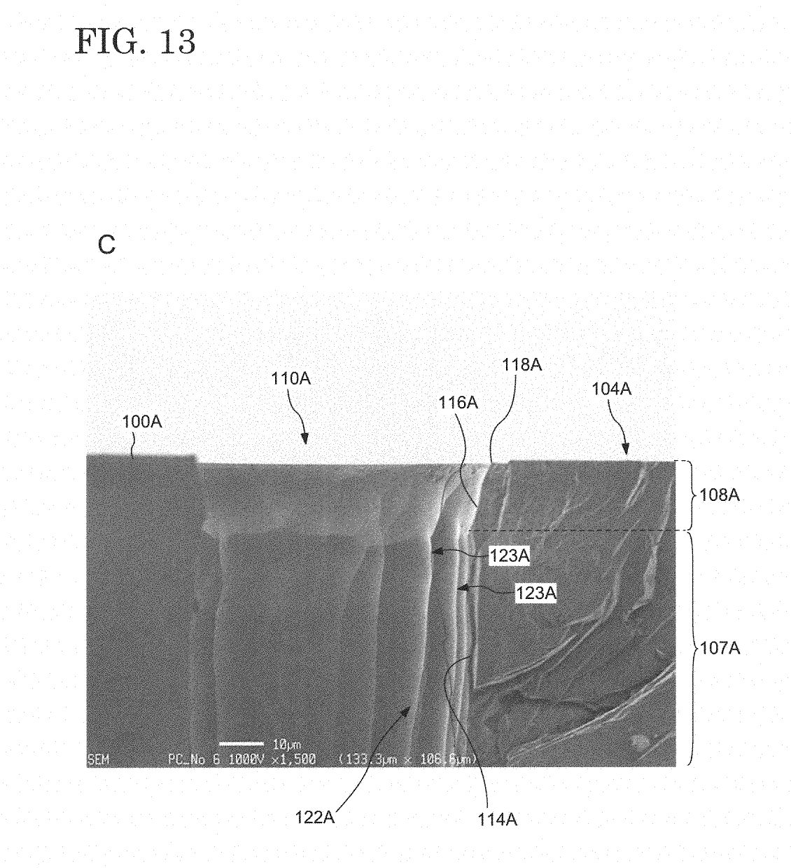

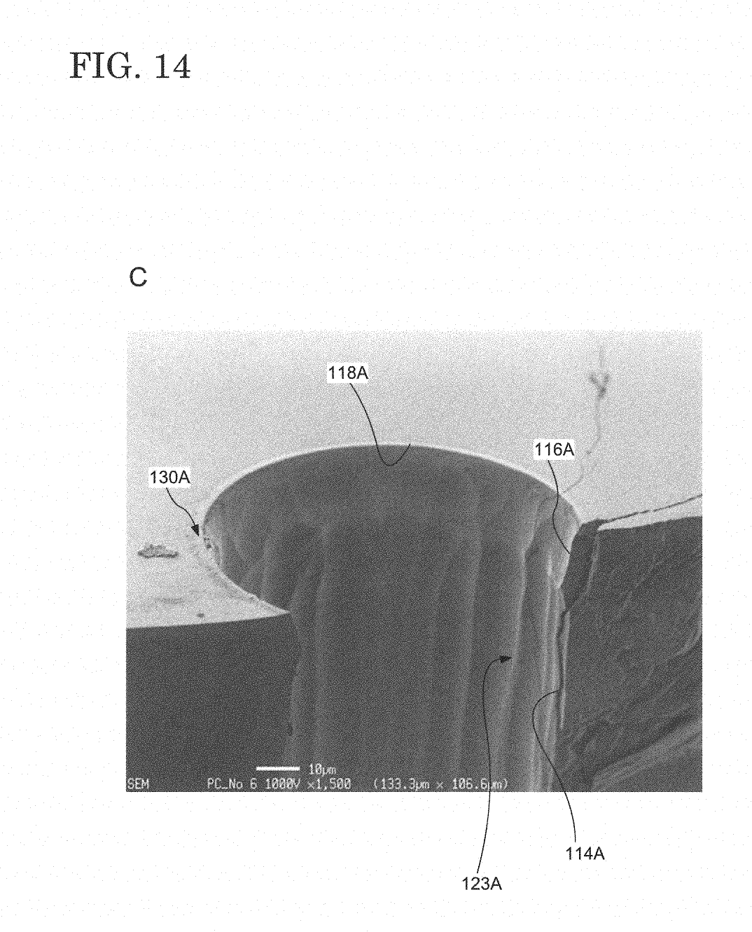

FIG. 13 is a cross-sectional SEM image of an enlarged region C in FIG. 10. FIG. 14 is a perspective SEM image of a sample in FIG. 13 observed diagonally from above. As is shown in FIG. 13 and FIG. 14, the uneven shape of the third inner wall 116A of the through-hole 110A in the third region 108A extends continuously from the uneven shape of the linear pattern 122A of the second inner wall 114A to the second surface 104A. That is, the linear shape of the linear pattern 122A of the second inner wall 114A also continues to the third inner wall 116A. However, the linear shape of the linear pattern 122A does not necessarily continue from the second inner wall 114A to the third inner wall 116A, and the linear pattern 122A of the second inner wall 114A may not continue to the third inner wall 116A. As is shown in FIG. 13 and FIG. 14, the line shape part of the linear pattern 122A is a convex part 123A. The third inner wall 116A inclines in a direction in which the size of the through-hole 110A is larger compared to the second inner wall 114A. That is, at an inclination angle with respect to a surface which is parallel to the second surface 104A, the inclination angle of the third inner wall 116A is smaller compared to the inclination angle of the second inner wall 114A. As is shown in FIG. 14, the projection part 130A encloses the second open end 118A.

As is described above, it is possible to form the through-hole 110A with the shapes shown in FIG. 10 to FIG. 14 by the formation method of the through-hole 110A related to the first embodiment. It is possible to form a through-hole electrode with good coverage inside the through-hole 110A by providing the through-hole 110A with the shapes described above. Furthermore, even in the case when the through-hole electrode which is arranged in the through-hole 110A receives an external force in the first direction D1, it is possible to suppress the through-hole electrode from detaching from the through-hole 110A.

### Second Embodiment

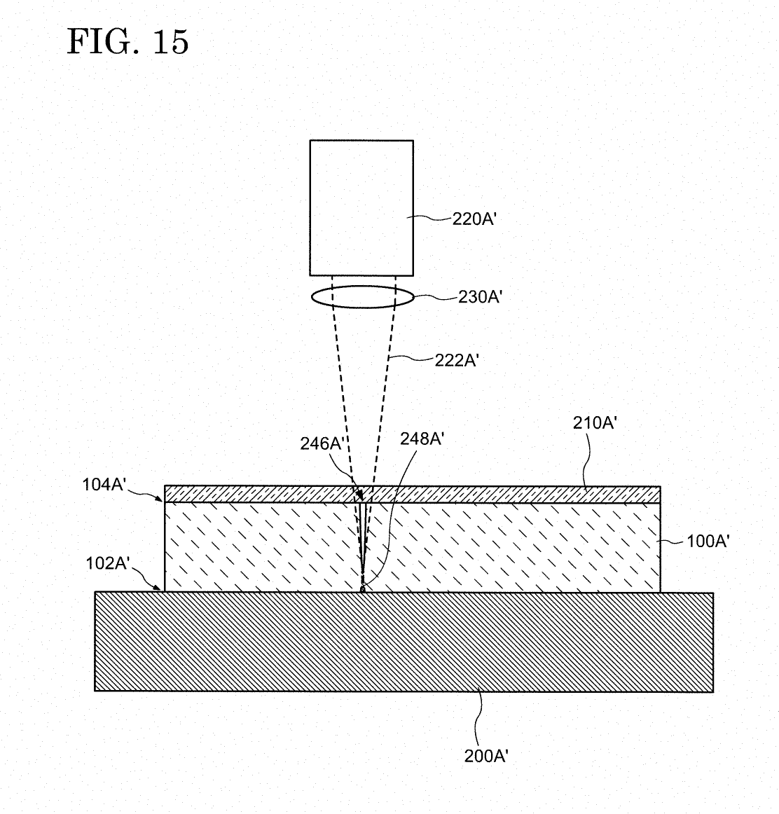

The formation method of a through-hole electrode substrate 10A′ related to the present embodiment is explained using FIG. 15 to FIG. 18. Since a substrate 100A′ which is used in the second embodiment is the same as the substrate 100 of the first embodiment, a detailed explanation is omitted. Although the shape of the through-hole 110A′ which is formed in the substrate 100A′ is the same as the shape of the through-hole 110 which is formed in the substrate 100 of the first embodiment, the formation method is different. A method of forming the through-hole 110A′ is explained below.

### [Method of Forming Through-Hole 110A′]

A method of forming the through-hole 110A′ which is arranged in the substrate 100A′ used for the through-hole electrode substrate 10A′ is explained using FIG. 15 to FIG. 18. Here, a method of forming the through-hole 110A′ in the substrate 100A′ using glass similar to the first embodiment is explained. Since the process of attaching a protective film 210A′ shown in FIG. 2 is the same as in the first embodiment, an explanation is omitted.

FIG. 15 is a cross-sectional diagram showing a process for irradiating a substrate with laser light in the method of manufacturing a substrate related to one embodiment of the present disclosure. By irradiating the substrate 100A′ with a laser from the side of the protective film 210A′, a concave part 246A′ is formed in a region of the substrate 100A′ where the through-hole 110A′ is formed. In other words, holes are formed in an upper region among the regions in which the through-hole 100A′ of the substrate 100A′ is formed. The laser light 222A′ which is emitted from a light source 220A′ is collected by a lens unit 230A′ and irradiated onto the substrate 100A′. The lens unit 230A′ is adjusted so that the laser light 222A′ is focused within the substrate 100A′. When the substrate 100A′ is irradiated with the laser light 222A′, a concave part 246A′ is formed by ablation of the substrate 100A′ in a region where the intensity of the laser light 222A′ is high.

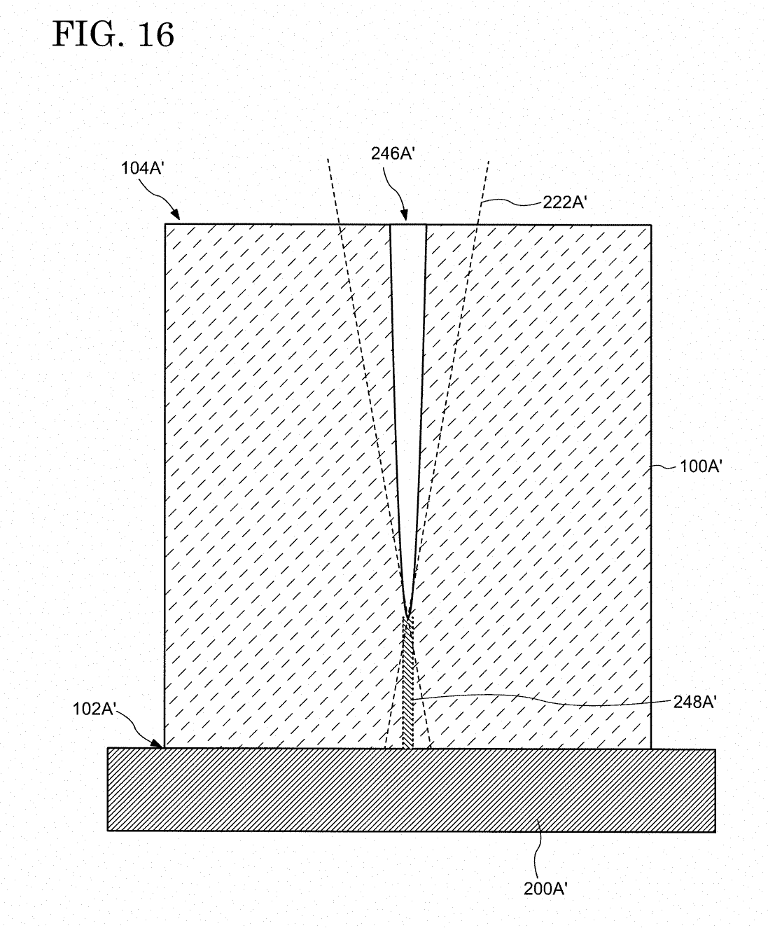

FIG. 16 is a cross-sectional diagram for explaining a concave part formed by laser irradiation in the method of manufacturing a substrate related to one embodiment of the present disclosure. As is shown in FIG. 16, the laser light 222A′ is focused within the substrate 100A′. In other words, the laser light 222A′ is focused between the first surface 102A′ and the second surface 104A′.

When the substrate 100A′ is irradiated with the laser light 222A′ which is focused within the inside of the substrate 100A′, a concave part 246A′ and a damaged part 248A′ are formed within the substrate 100A′. The concave part 246A′ is formed on the second surface 104A′ side. The damaged part 248A′ is formed on the first surface 102A′ side. A boundary exists between the concave part 246A′ and the damaged part 248A′ in vicinity of the focal point of the laser light 222A′. The concave part 246A′ is a region where a part of the substrate 100A′ has disappeared by continuously irradiating the laser light 222A′. In other words, the concave part 246A′ is a continuous concave shaped space. Unlike the concave part 246A′, the damaged part 248A′ is a region in which a discontinuous space is formed. In other words, the damaged part 248A′ is a region in which an aggregate of shapes such as cracks or voids for example is discretely formed. The damaged part 248A′ is a region where a continuous space such as the concave part 246A′ is not formed even when the laser light 222A′ is continuously irradiated. Even if it is assumed that a process is performed below the condition that the output of the laser light 222A′ is increased and a space which is continuous to the damaged part 248A′ is formed, the size of the continuous space which is formed in the region corresponding to the damaged part 248A′ is smaller than the concave part 246A′.

Although a structure is exemplified in FIG. 16 in which the boundary between the concave part 246A′ and the damaged part 248A′ matches the position of the focal point of the laser light 222A′, the present invention is not limited to this structure. The boundary between the concave part 246A′ and the damaged part 248A′ may be located further on the first surface 102A′ side than the focal point of the laser light 222A′, or may be located further on the second surface 104A′ side than the focal point of the laser light 222A′. The laser light 222A′ which has passed through the substrate 100A′ is absorbed by a processing stage 200A′ on the first surface 102A′ side.

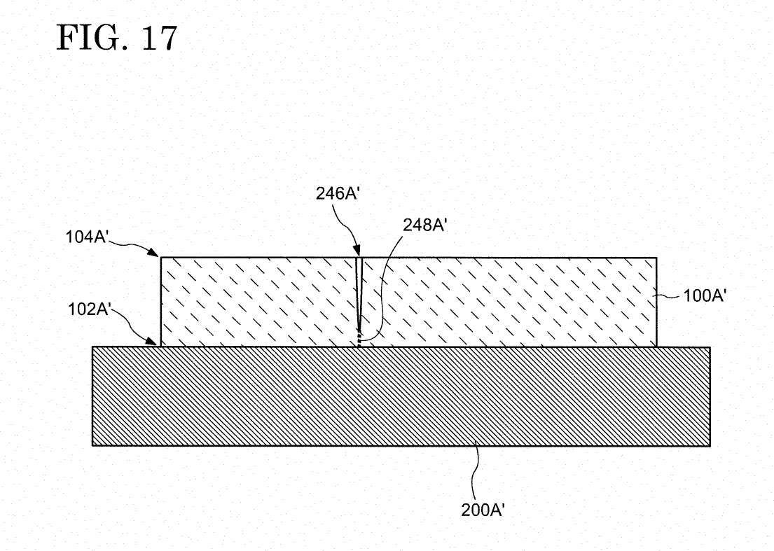

FIG. 17 is a cross-sectional diagram showing a process of peeling a film from a substrate in the method of manufacturing a substrate related to one embodiment of the present disclosure. After forming the concave part 246A′ and the damaged part 248A′ are formed in the substrate 100A′ by laser irradiation, the protective film 210A′ is peeled off from the substrate 100A′. After the protective film 210A′ is peeled off, the substrate 100A′ is washed. Sulfuric acid/hydrogen peroxide cleaning (SPM), ammonia/hydrogen peroxide cleaning (APM) and ozone water or the like can be used for cleaning the substrate 100A′.

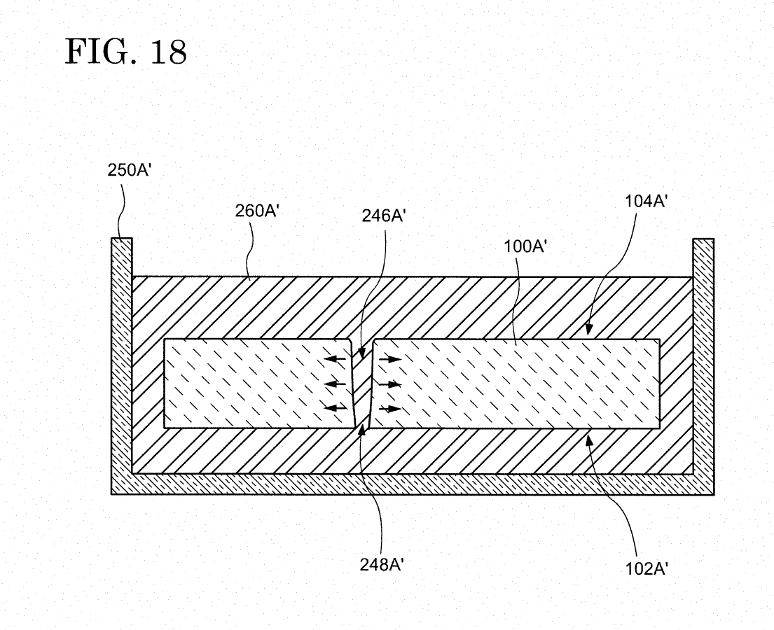

FIG. 18 is a cross-sectional diagram showing a process for etching the concave and damaged layers of a substrate in the method of manufacturing a substrate related to one embodiment of the present disclosure. When the substrate 100A′ in the state shown in FIG. 17 is immersed in a chemical solution, the chemical solution enters into the inside of the concave part 246A′. The substrate 100A′ on the inner wall and bottom part of the concave part 246A′ is etched by the chemical solution, and the concave part 246A′ widens in the depth and diameter direction thereof. The chemical solution etches the damaged part 248A′ entering in the depth direction of the concave part 246A′. When the chemical solution reaches the damaged part 248A′, the chemical solution continues to etch the substrate 100A′ while widening the discontinuous space of the damaged part 248A′. The space widened by the chemical solution eventually becomes continuous with the space adjacent to this space, and etching of the damaged part 248A′ proceeds. Etching of the damaged part 248A′ proceeds not only from the second surface 104A′ side but also from the first surface 102A′ side.

The surface state after etching of the region where the damaged part 248A′ is formed becomes a granular patterned uneven shape due to a difference in the progress of the etching described above, and the surface state after etching of the region where the concave part 246A′ is formed becomes a linear patterned uneven shape. That is, when the damaged layer 248A′ is etched, the first inner wall 112A′ of the granular pattern 120A′ is formed, and when the concave part 246A′ is etched, the second inner wall 114A′ of the linear pattern 122A′ is formed. Furthermore, the vicinity of the second surface 104A′ of the concave part 246A′ is etched in the direction in which the size of the through-hole 110A′ is widened by the etching described above, and the third inner wall 116A′ is formed.

As is described above, it is possible to form the first inner wall 112A′, the second inner wall 114A′ and the third inner wall 116A′ having different surface states by the formation method shown in the second embodiment.

### Third Embodiment

### [Structure of Through-Hole Electrode Substrate 10B]

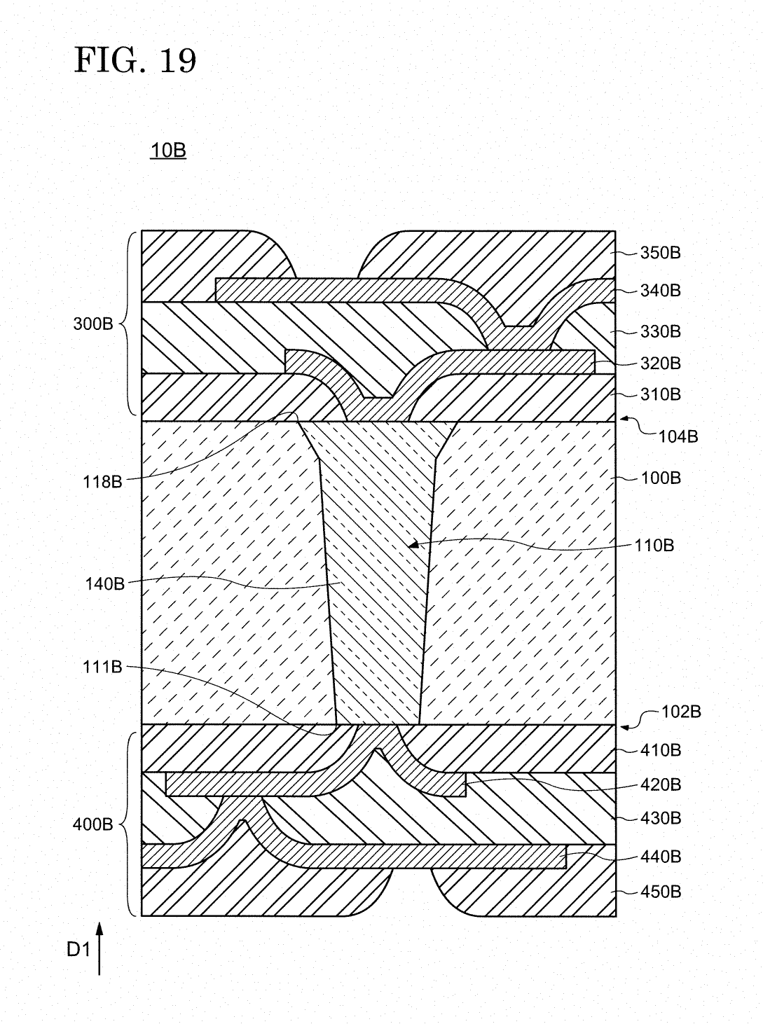

The shape of the through-hole electrode substrate 10B related to the present embodiment is explained using FIG. 19 to FIG. 24. Since the substrate 100B used in the third embodiment is the same as the substrate 100 of the first embodiment, a detailed explanation is omitted.

As is shown in FIG. 19, the through-hole electrode substrate 10B includes a substrate 100B, a through-hole electrode 140B, a first stacked wiring 300B and a second stacked wiring 400B. A through-hole 110B is arranged in the substrate 100B. The shape of the through-hole 110B is the same as the shape (refer to FIG. 1) of the through-hole 110 explained in the first embodiment. The through-hole electrode 140B is filled in the through-hole 110B.

The first stacked wiring 300B includes a first insulating layer 310B, a first wiring 320B, a second insulating layer 330B, a second wiring 340B and a third insulating layer 350B. The first insulating layer 310B is arranged on the second surface 104B of the substrate 100B. An open part is arranged in the first insulating layer 310B, and the open part is arranged in a region further to the inside than the second open end 118B in a planar view. That is, the first insulating layer 310B contacts the through-hole electrode 140B. The first wiring 320B is arranged on the first insulating layer 310B and is connected to the through-hole electrode 140B through an open part arranged in the first insulating layer 310B. The second insulating layer 330B is arranged on the first wiring 320B. The second insulating layer 330B is arranged with an open part which exposes a part of the first wiring 320B. The second wiring 340B is arranged on the second insulating layer 330B and is connected to the first wiring 320B through an open part arranged in the second insulating layer 330B. The third insulating layer 350B is arranged on the second wiring 340B. The third insulating layer 350B is arranged with an open part which exposes a part of the second wiring 340B. A connection member such as a bump is arranged in the open part of the third insulating layer 350B.

The second stacked wiring 400B includes a fourth insulating layer 410B, a third wiring 420B, a fifth insulating layer 430B, a fourth wiring 440B, and a sixth insulating layer 450B. The fourth insulating layer 410B is arranged below the first surface 102B of the substrate 100B. An open part is arranged in the fourth insulating layer 410B and the open part is arranged in a region further to the inside than the first open end 111B in a planar view. That is, the fourth insulating layer 410B contacts the through-hole electrode 140B. The third wiring 420B is arranged below the fourth insulating layer 410B and is connected to the through-hole electrode 140B through an open part which is arranged in the fourth insulating layer 410B. The fifth insulating layer 430B is arranged below the third wiring 420B. The fifth insulating layer 430B is arranged with an open part which exposes a part of the third wiring 420B. The fourth wiring 440B is arranged below the fifth insulating layer 430B and is connected to the third wiring 420B through an open part which is arranged in the fifth insulating layer 430B. The sixth insulating layer 450B is arranged below the fourth wiring 440B. The sixth insulating layer 450B is arranged with an open part which exposes a part of the fourth wiring 440B. A connection member such as a bump is arranged in the open part of the sixth insulating layer 450B.

By arranging a connecting member such as a bump in each open part of the third insulating layer 350B and the sixth insulating layer 450B and mounting an integrated circuit and the like on each bump respectively, it is possible to use the through-hole electrode substrate 10B as an interposer.

As described above, according to the through-hole electrode substrate 10B related to the third embodiment, even in the case when the through-hole electrode 140B which is arranged in the through hole 110B receives an external force in the first direction D1, it is possible to suppress the through-hole electrode 140B from being detached from the through-hole 110B.

### [Manufacturing Method of Through-Hole Electrode Substrate 10B]

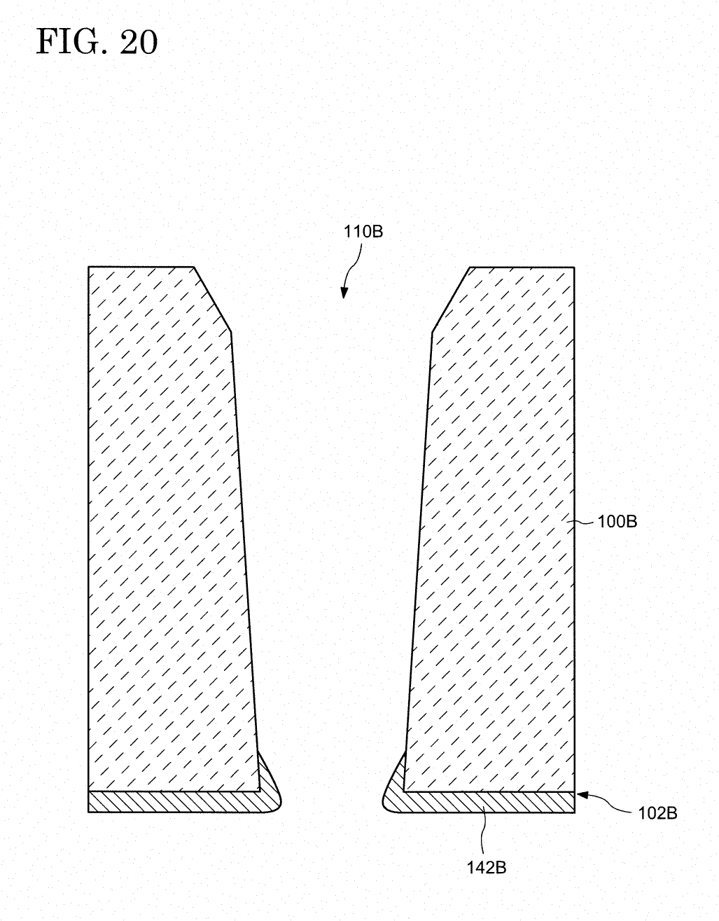

A method of manufacturing the through-hole electrode substrate 10B is explained using FIG. 20 to FIG. 25. Here, a method of forming a through-hole electrode by a method of forming a lid plating which covers one end part of the through-hole 110B and growing a plating layer inside the through-hole 110B using the lid plating as a seed is explained.

FIG. 20 is a cross-sectional diagram showing a step for forming a seed layer on the first surface side in the method of manufacturing a through-hole electrode substrate related to one embodiment of the present disclosure. As is shown in FIG. 20, a seed layer 142B is formed on the first surface 102B side of the substrate 100B. The seed layer 142B is formed by a PVD method (a vacuum evaporation method, a sputtering method, or the like) or a CVD method and the like. A metal such as copper (Cu), titanium (Ti), tantalum (Ta), tungsten (W), nickel (Ni) or chromium (Cr) and the like is used as the seed layer 142B. Alternatively, an alloy using these metals may also be used. These metals or alloys may be used in a single layer or in stacked layers. For example, the same material as the first plating layer 144B which is formed later on the seed layer 142B may be used as the seed layer 142B.

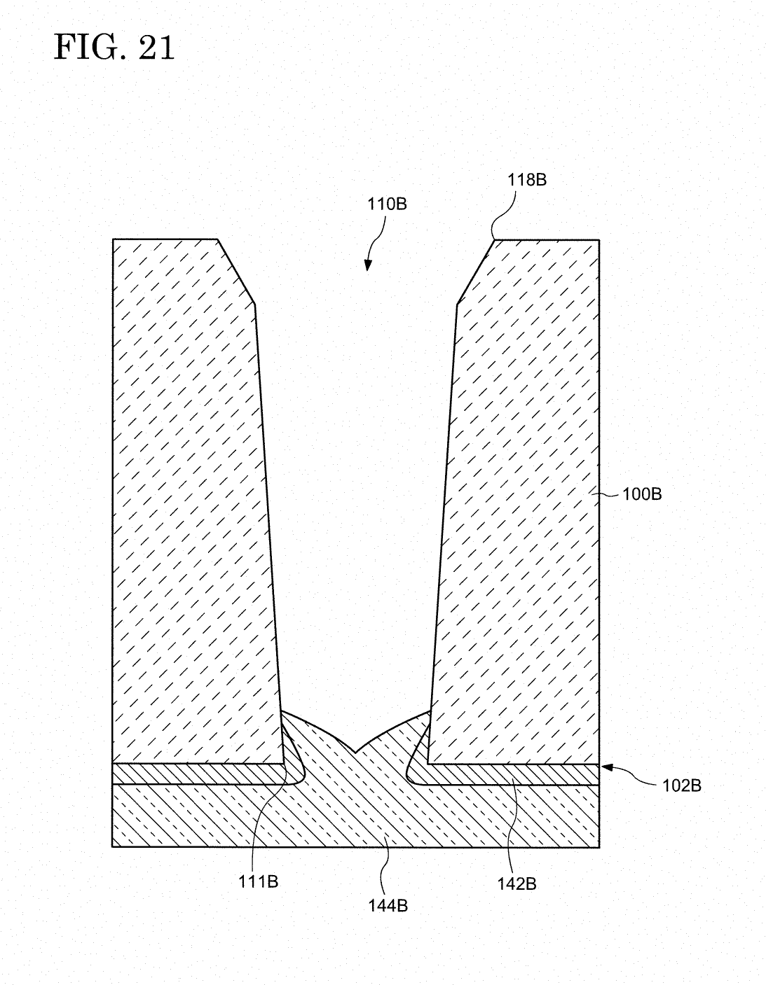

FIG. 21 is a cross-sectional diagram showing a step for forming a plating layer which covers an open part on a first surface side in the method of manufacturing a through-hole electrode substrate related to one embodiment of the present disclosure. As is shown in FIG. 21, a first plating layer 144B is formed on a seed layer 142B. The first plating layer 144B is formed by an electric field plating method in which a plating layer is grown by conducting electricity to the seed layer 142B. The formation of the first plating layer 144B is performed in a state in which a plating solution is supplied to the entire seed layer 142B which is exposed to the surface. By growing the first plating layer 144B from the seed layer 142B, an open part on the first surface 102B side of the through-hole 110B is covered by the first plating layer 144B. The first plating layer 144B can also be called lid plating.

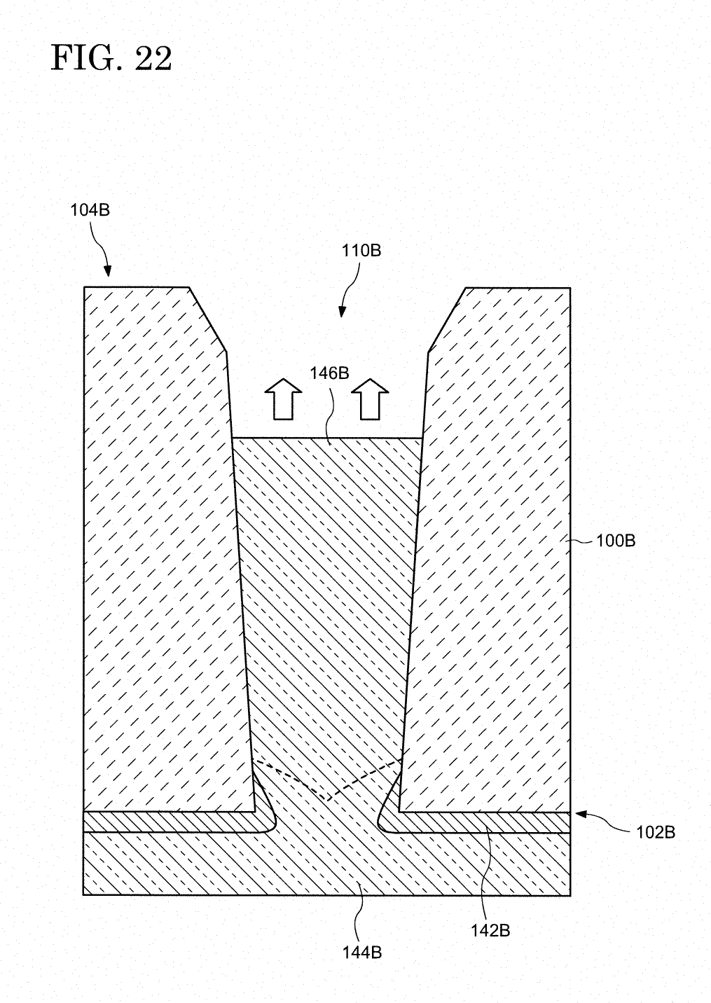

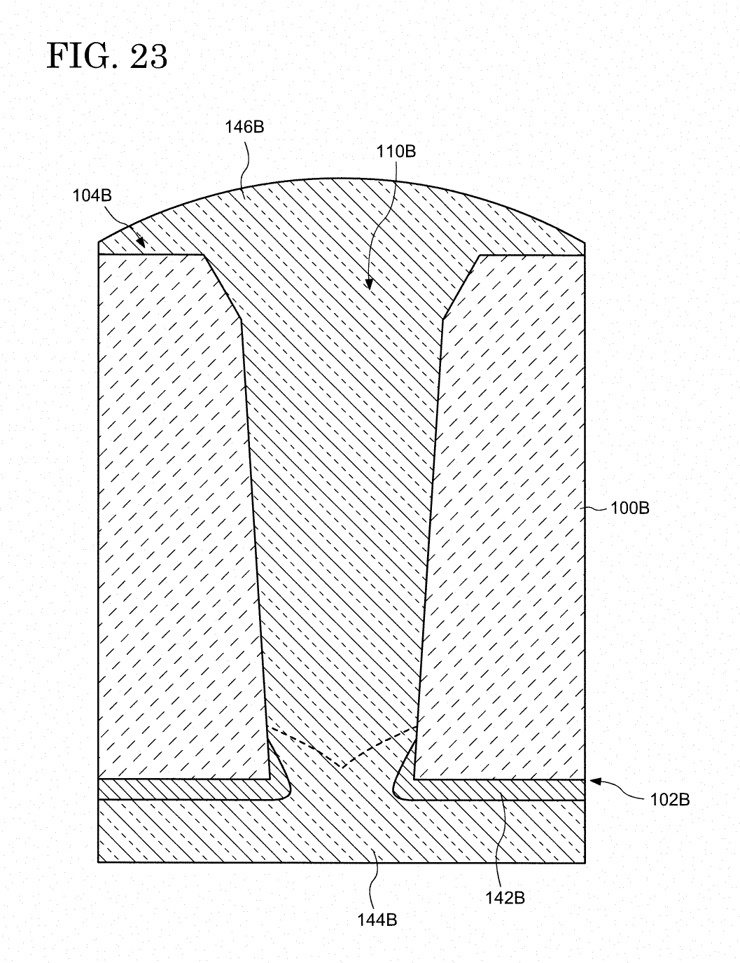

FIG. 22 is a cross-sectional diagram showing a step for growing a plating layer from the first surface side toward a second surface in the method of manufacturing a through-hole electrode substrate related to one embodiment of the present disclosure. As is shown in FIG. 22, the second plating layer 146B is formed on the first plating layer 144B. The second plating layer 146B is formed by an electric field plating method in which to a plating layer is grown by conducting electricity to the first plating layer 144B. The formation of the second plating layer 146B is performed in a state where a plating solution is supplied to the first plating layer 144B which is exposed in the through-hole 1106. The second plating layer 146B grows the inside the through-hole 1106 from the first surface 1026 side toward the second surface 1046 side from the first plating layer 144B which is exposed in the through-hole 1106. As is shown in FIG. 23, the second plating layer 146B fills the interior of the through-hole 1106, grows further and is also formed on the second surface 104B side of the substrate 100B. At this time, since the second plating layer 146B on the second surface 1046 side is grown radially from the through-hole 1106 toward the outside on the second surface 104B side, it is formed in a dome shape as is shown in FIG. 23. When forming the second plating layer 146B, the plating solution may be supplied to the entire first plating layer 144B. That is, the second plating layer 146B may be formed not only on the interior of the through-hole 1106 but also below the first plating layer 144B.

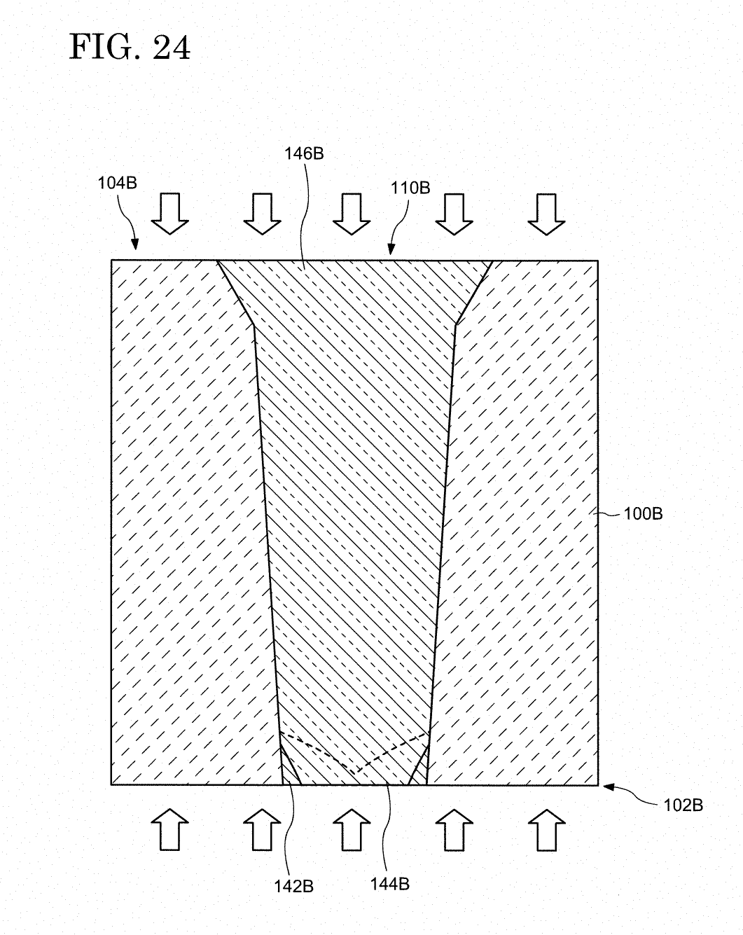

FIG. 24 is a cross-sectional diagram showing a step for polishing the seed layer and the plating layer formed on the first surface and the plating layer formed on the second surface in a method of manufacturing a through-hole electrode substrate related to one embodiment of the present disclosure. As is shown in FIG. 24, the seed layer 142B and the first plating layer 144B which are formed below the first surface 102B are polished to expose the first surface 102B of the substrate 100B. Similarly, the second plating layer 146B which is formed on the second surface 104B is polished to expose the second surface 104B of the substrate 100B. As is shown in FIG. 24, in the case when the through-hole electrode substrate 10B is manufactured by the manufacturing method described above, although the seed layer 142B which has not been polished remains on the first surface 102B side on the inside of the through-hole 110B, the seed layer is not present on the second surface 104B side. However, in FIG. 19 and other diagrams, for the convenience of explanation the seed layer 142B formed on the inside of the through-hole 110B is omitted. By forming an insulating layer and a conductive layer on the substrate 100B shown in FIG. 24 and repeating photolithography and etching, the first stacked wiring 300B and the second stacked wiring 400B are respectively formed on the second surface 104B and the first surface 102B.

As described above, according to the method of manufacturing the through-hole electrode substrate 10B related to the third embodiment, since the size of the through-hole 110B gradually increases from the first surface 102B to the second surface 104B, it is possible to suppress a void being formed in the second plating layer 146B in the case where the second plating layer 146B is grown from the first surface 102B side. Furthermore, since the size of the first open end 111B is smaller than the size of the second open end 118B, there is an advantage whereby it is possible to shorten the time when the open part on the first surface 102B side is covered by the first plating layer 144B.

In addition, in the through-hole electrode substrate 10B of the present embodiment, similar to the through-hole electrode substrate 10 shown in FIG. 1, the second inner wall 114 of the through-hole 110 in the second region 107 is formed with a linear patterned 122 uneven shape. Therefore, the growth direction of the second plating layer 146B is controlled in the direction in which the line of the linear pattern 122B extends. The crystallinity of the second plating layer 146B is also controlled by controlling the growth direction of the second plating layer 146B as described above. Since the grain size of the crystal grains of the second plating layer 146B increase in the direction in which the line of the linear pattern 122B extends by this control, it is possible to realize the through-hole electrode 140B with a low electrical resistance and a strong resistance to stress such as electromigration and the like.

### Fourth Embodiment

### [Structure of Through-Hole Electrode Substrate 10C]

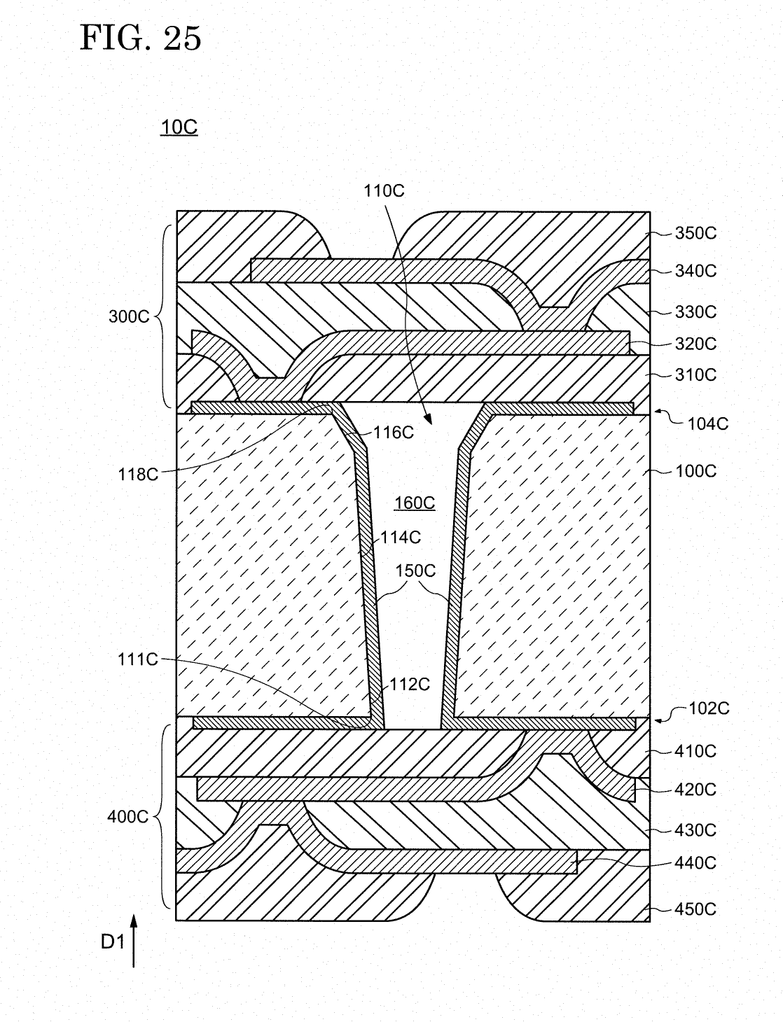

The shape of a through-hole electrode substrate 10C related to the present embodiment is explained using FIG. 25. Since a substrate 100C, a first stacked wiring 300C and a second stacked wiring 400C used in the fourth embodiment are the same as the substrate 100B, the first stacked wiring 300B and the second stacked wiring 400B of the third embodiment, a detailed explanation is omitted. In the explanation below, differences from the through-hole electrode substrate 10B of the third embodiment are explained.

As is shown in FIG. 25, the through-hole electrode 150C of the through-hole electrode substrate 10C is arranged along the first inner wall 112C, the second inner wall 114C, the third inner wall 116C, the first surface 102C and the second surface 104C of the through-hole 110C. A gap 160C is arranged further inside than the through-hole electrode 150C of the through-hole 110C. That is, in the through-hole electrode substrate 10C, the through-hole 110C is not filled with the through-hole electrode 150C. An open part of the first insulating layer 310C is arranged on the second surface 104C of the substrate 100C. That is, the open part of the first insulating layer 310C is arranged in a region which does not overlap the through-hole 110C in a planar view. Similar to the first insulating layer 310C, an open part of the fourth insulating layer 410C is also arranged below the first surface 102C of the substrate 100C. That is, the open part of the fourth insulating layer 410C is arranged in a region which does not overlap the through-hole 110C in a planar view.

The through-hole electrode 150C is formed from each surface side of the first surface 102C side and the second surface 104 side by a PVD method (a vacuum evaporation method or a sputtering method and the like). Furthermore, wiring which is electrically independent of the through-hole electrode 150C may be formed on the first surface 102C and the second surface 104C in the same process as the formation of the through-hole electrode 150C. After forming a metal thin film by a PVD method, a plating layer may be formed on the metal thin film by an electrolytic plating method with the metal thin film as a seed layer. In this case, the through-hole electrode 150C may be formed by forming a metal thin film of several hundred nano meters by a PVD method and forming a plating layer of several micro meters thereon. The through-hole electrode 150C may also be formed by electroless plating using a method other than a PVD method. The electroless plating method is, for example, a method of growing a plating layer in a region which contacts a plating solution by bringing the plating solution including at least copper ions into contact with the side wall, the first surface 102C and the second surface 104C of the through-hole 110C. The plating solution includes, for example, copper compounds such as copper sulfate for providing copper ions, and additives such as formaldehyde and sodium hydroxide. Furthermore, as described above, after forming the first plating layer using an electroless plating method, the second plating layer may be formed thereon by an electroplating method with the first plating layer as a seed layer.

The first insulating layer 310C and the fourth insulating layer 410C may be formed by attaching a sheet shaped insulating material. In the case of this type of structure, it is preferred to use materials which can easily pass through such as gas or moisture as the first insulating layer 310C and the fourth insulating layer 410C. Even if the gap 160C is filled with gas or moisture, since the first insulating layer 310C and the fourth insulating layer 410C have a permeability to gas or moisture, the gas or moisture passes through the first insulating layer 310C and the fourth insulating layer 410C and is discharged to the exterior from the gap 160C. Therefore, it is possible to suppress problems such as bursting caused by an increase in internal pressure of the gap 160C.

As described above, according to the through-hole electrode substrate 10C related to the fourth embodiment, even when the through-hole electrode 150C which is arranged inside the through-hole 110C receives an external force in the first direction D1, it is possible to suppress the through-hole electrode 150C from being detached from the through-hole 110C. Furthermore, since the through-hole electrode 150C is not filled in the through-hole 110C, the consumption of the material used for the through-hole electrode 150C is reduced and the time for forming the through-hole electrode 150C is shortened. Therefore, it is possible to reduce the manufacturing costs of the through-hole electrode substrate 10C.

### Fifth Embodiment

### [Structure of Through-Hole Electrode Substrate 10D]

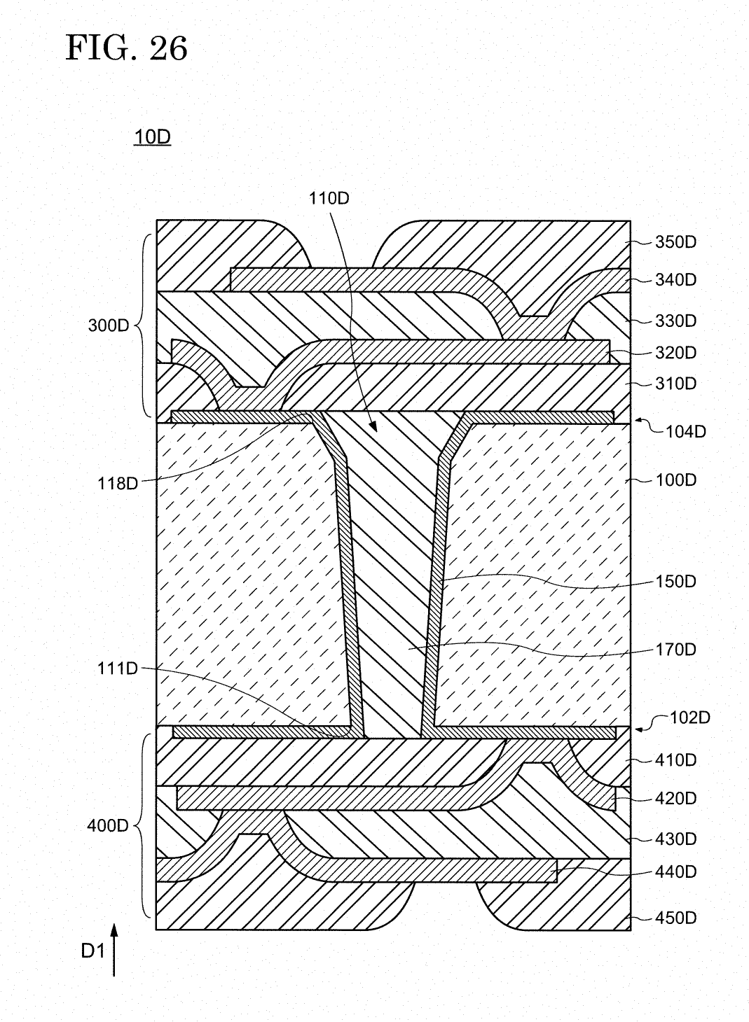

The shape of the through-hole electrode substrate 10D related to the present embodiment is explained using FIG. 26. Since a substrate 100D, a through-hole electrode 150D, a first stacked wiring 300D and a second stacked wiring 400D used in the fifth embodiment are the same as the substrate 100C, the through-hole electrode 150C, the first stacked wiring 300C and the second stacked wiring 400C of the fourth embodiment, a detailed explanation is omitted. In the explanation below, differences from the through-hole electrode substrate 10C of the fourth embodiment are explained.

As is shown in FIG. 26, a filler 170D is arranged further inside than the through-hole electrode 150D of the through-hole 110D. That is, the gap 160C shown in FIG. 25 is filled with the filler 170D. The filler 170D may have insulating or conductive properties. The filler 170D may be a resin material or an inorganic material. In FIG. 26, similar to FIG. 25, although an open part of the first insulating layer 310D is arranged on the second surface 104D of the substrate 100D, the present invention is not limited to this structure. For example, similar to FIG. 19, an open part of the first insulating layer 310D may be arranged in a region which overlaps the through-hole 110D in a planar view.

As described above, according to the through-hole electrode substrate 10D related to the fifth embodiment, even when the through-hole electrode 150D which is arranged within the through-hole 110D receives an external force in the first direction D1, it is possible to suppress the through-hole electrode 150D from being detached from the through-hole 110D. Furthermore, by filling the filler 170D further to the inner side of the through-hole electrode 150D of the through-hole 110D, restrictions on the formation of the first insulating layer 310D and the fourth insulating layer 410D is relaxed.

### Sixth Embodiment

In the sixth embodiment, a semiconductor device manufactured using the through-hole electrode substrates 10B to 10D shown in the third to fifth embodiments are explained. In the explanation below, a semiconductor device which uses the through-hole electrode substrates 10B to 10D shown in the third to fifth embodiments as an interposer is explained.

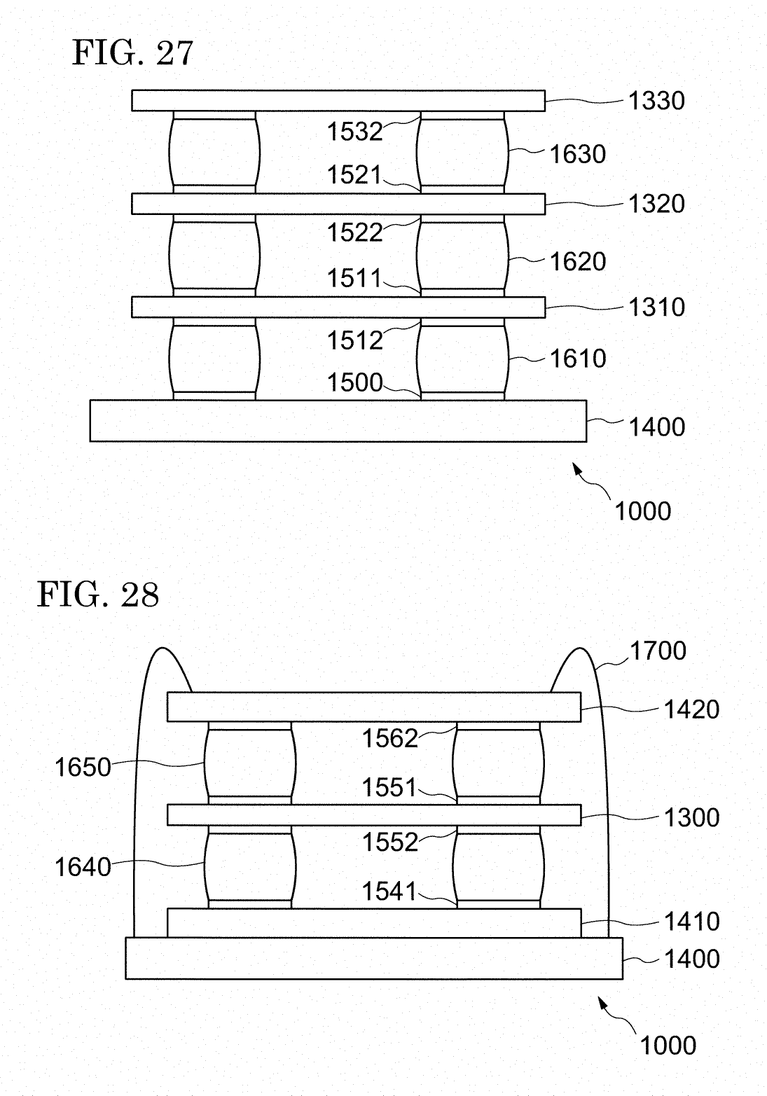

FIG. 27 is a cross-sectional diagram showing a semiconductor device using the through-hole electrode substrate related to one embodiment of the present disclosure. In the semiconductor device 1000, three through-hole electrode substrates 1310, 1320, and 1330 are stacked and, for example, are connected to an LSI substrate 1400 in which a semiconductor element such as a DRAM is formed. The through-hole electrode substrate 1310 includes a connection terminal 1511 and a connection terminal 1512. The through-hole electrode substrate 1320 includes a connection terminal 1521 and a connection terminal 1522. The through-hole electrode substrate 1330 includes a connection terminal 1532. The connection terminals 1511 and 1521 correspond to, for example, the second wiring 340B which is exposed in the open part arranged in the third insulating layer 350B shown in FIG. 19. The connection terminals 1512, 1522, and 1532 correspond to, for example, the fourth wiring 440B which is exposed in the open part arranged in the sixth insulating layer 450B shown in FIG. 19.

The material of each substrate of the through-hole electrode substrates 1310, 1320 and 1330 may also be different. The connection terminal 1512 is connected to the connection terminal 1500 of the LSI substrate 1400 by a bump 1610. The connection terminal 1511 is connected to the connection terminal 1522 by a bump 1620. The connection terminal 1521 is connected to the connection terminal 1532 by a bump 1630. For example, metals such as indium, copper and gold and the like are used as the bumps 1610, 1620 and 1630.

The number of stacked layers of a through-hole electrode substrate is not limited to three and may be two or four or more. The connection between the pairs of facing through-hole electrode substrates is not limited to a connection through bumps and other bonding techniques such as eutectic bonding may also be used. Pairs of facing through-hole electrode substrates may be attached to each other by applying a polyimide or an epoxy resin or the like and baking as another connection method.

FIG. 28 is a cross-sectional diagram showing another example of the semiconductor device using the through-hole electrode substrate related to one embodiment of the present disclosure. In the semiconductor device 1000 shown in FIG. 28, semiconductor chips (LSI chips) 1410 and 1420 such as a MEMS device, a CPU and a memory, and a through-hole electrode substrate 1300 are stacked and connected to the LSI substrate 1400.

The through-hole electrode substrate 1300 is arranged between the semiconductor chip 1410 and the semiconductor chip 1420. The semiconductor chip 1410 and the through-hole electrode substrate 1300 are connected by a bump 1640. The semiconductor chip 1420 and the through-hole electrode substrate 1300 are connected by a bump 1650. The semiconductor chip 1410 is mounted on the LSI substrate 1400 and the LSI substrate 1400 and the semiconductor chip 1420 are connected by a wire 1700. In this example, the through-hole electrode substrate 1300 performs the role of connecting a plurality of semiconductor chips having different functions respectively, and a multifunctional semiconductor device is realized. For example, by using the semiconductor chip 1410 as a three-axis acceleration sensor and the semiconductor chip 1420 as a two-axis magnetic sensor, it is possible to realize a five-axis motion sensor in one module.

In the case when the semiconductor chip is a sensor such as a MEMS device, the sensing result may sometimes be output as an analog signal. In this case, a low pass filter or an amplifier and the like may be formed on the semiconductor chip or the through-hole electrode substrate 1300.

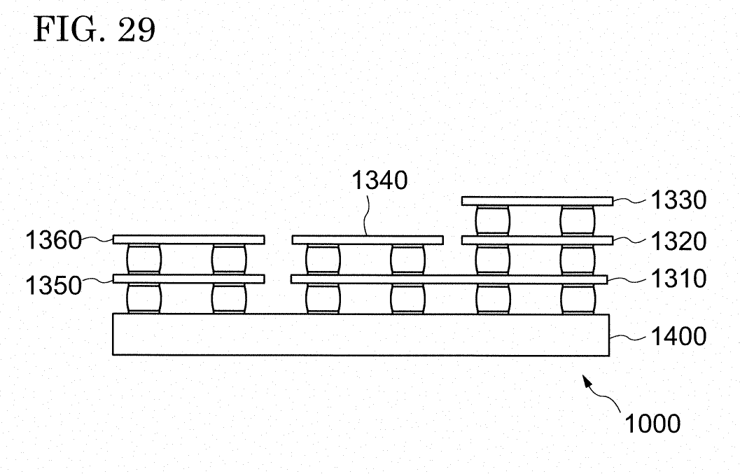

FIG. 29 is a cross-sectional diagram showing still another example of the semiconductor device using the through-hole electrode substrate related to one embodiment of the present disclosure. Although the two examples described above (FIG. 27 and FIG. 28) are three-dimensional mounted, the example shown in FIG. 29 is an example applied to combined mounting in two dimensions and three dimensions (sometimes called 2.5 dimensions). In the example shown in FIG. 29, six through-hole electrode substrates 1310, 1320, 1330, 1340, 1350 and 1360 are stacked on the LSI substrate 1400. However, not only are all the through-hole electrode substrates are stacked, they are also arranged in a substrate in-plane direction. The material of each substrate of these through-hole electrode substrates may also be different.

In FIG. 29, the through-hole electrode substrates 1310 and 1350 are connected on the LSI substrate 1400, the through-hole electrode substrates 1320 and 1340 are connected above the through-hole electrode substrate 1310, the through-hole electrode substrate 1330 is connected above the through-hole electrode substrate 1320, and the through-hole electrode substrate 1360 is connected above the through-hole electrode substrate 1350. As is shown in FIG. 29, these through-hole electrode substrates can be used as an interposer for connecting a plurality of semiconductor chips, and can be combined and mounted in two and three dimensions. The through-hole electrode substrates 1330, 1340, 1360 may also be replaced with a semiconductor chip.

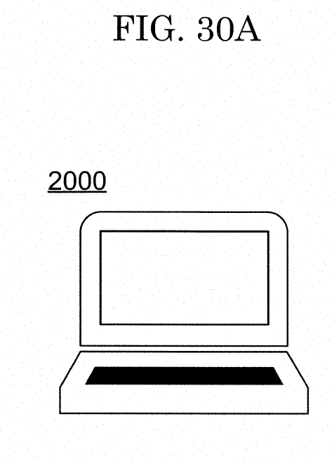

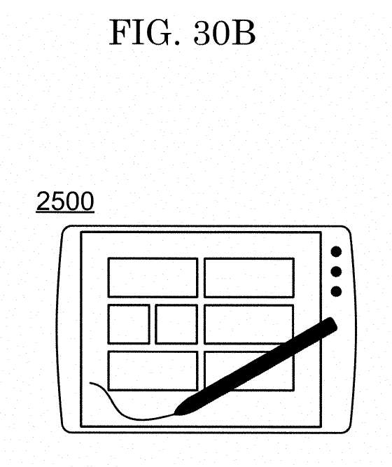

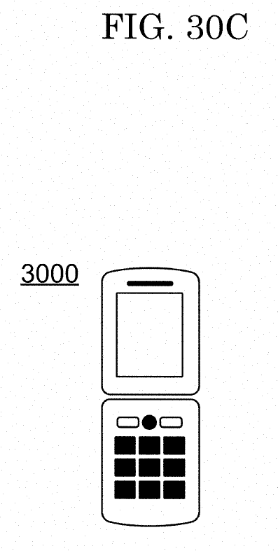

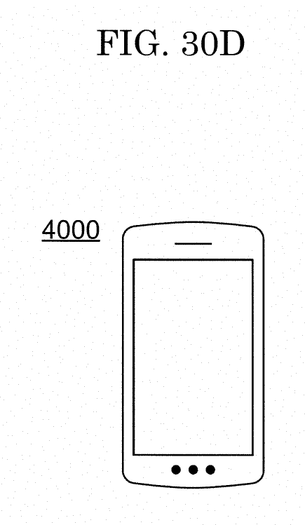

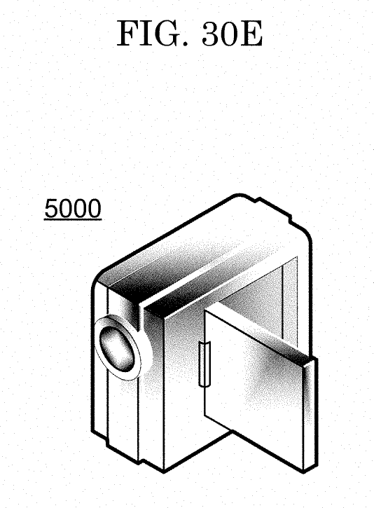

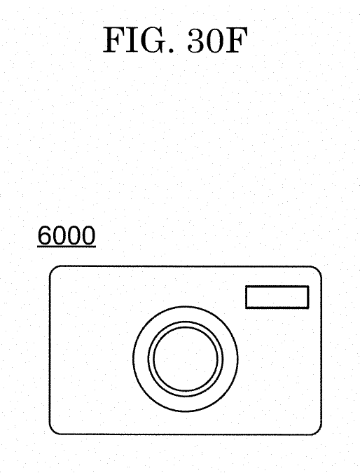

FIG. 30A to 30F are diagrams showing an example of an electronic device using the through-hole electrode substrate related to one embodiment of the present disclosure as an interposer. As is shown in FIG. 30A to 30F, the through-hole electrode substrates 10B to 10D shown in the third to fifth embodiments are used in a notebook personal computer 2000, a tablet terminal 2500, a mobile phone 3000, a smartphone 4000 and a digital video camera 5000 and a digital camera 6000 and the like. In addition to the electronic devices described above, the through-hole electrode substrates 10B to 10D can also be used in desktop personal computers, servers and car navigation systems and the like.

Furthermore, the present disclosure is not limited to the embodiments described above and can be appropriately modified within a scope that does not depart from the gist of the invention.

What is claimed is:

1. A through-hole electrode substrate comprising:
a substrate having a first surface, a second surface on an opposite side of the first surface and a through-hole passing through from the first surface to the second surface;
an inner wall of the through-hole divided into a first inner wall, a second inner wall and a third inner wall from the first surface side;
a size of a first open end of the through-hole in the first surface side is smaller than a size of a second open end of the through-hole in the second surface side;
an incline angle with respect to the first surface and the second surface of the third inner wall is smaller than an incline angle with respect to the first surface and the second surface of the second inner wall and the third inner wall; and
a through-hole electrode arranged on the interior of the through-hole and electrically connecting wiring arranged on the first surface side and wiring arranged on the second surface side.

2. The through-hole electrode substrate according to claim 1, wherein a surface shape of the first inner wall is a granular patterned uneven shape.

3. The through-hole electrode substrate according to claim 2, wherein a surface shape of the second inner wall is a linear patterned uneven shape extending in a direction intersecting the first surface and the second surface.

4. The through-hole electrode substrate according to claim 2, wherein
a surface shape of the second inner wall is a granular patterned uneven shape, and
a granular shape of the granular patterned uneven shape of the second inner wall extending in a direction intersecting the first surface and the second surface than a granular shape of the granular patterned uneven shape of the first inner wall.

5. The through-hole electrode substrate according to claim 1, wherein a surface shape of the second inner wall is a linear patterned uneven shape extending in a direction intersecting the first surface and the second surface.

6. The through-hole electrode substrate according to claim 1, wherein
a surface shape of the second inner wall is a granular patterned uneven shape, and
a granular shape of the granular patterned uneven shape of the second inner wall extending in a direction intersecting the first surface and the second surface than a granular shape of the granular patterned uneven shape of the first inner wall.

7. The through-hole electrode substrate according to claim 1, wherein
a surface shape of the first inner wall is an uneven shape, and
a surface shape of the second inner wall is an uneven shape different to the uneven shape of the first inner wall and extending in a direction intersecting the first surface and the second surface.

8. The through-hole electrode substrate according to claim 1, further comprising:
a projection part on the second surface in the vicinity of the second open end, the projection part projecting from the second surface in a direction opposite to the first surface.

9. The through-hole electrode substrate according to claim 8, wherein the projection part consecutively surrounds the second open end in a planar view.

10. The through-hole electrode substrate according to claim 1, wherein the through-hole electrode fills the interior of the through-hole.

11. The through-hole electrode substrate according to claim 1, wherein
the through-hole electrode is arranged on the first inner wall, the second inner wall and the third inner wall, and
a gap is arranged further to the inner side than the through-hole electrode with respect to the through-hole.

12. The through-hole electrode substrate according to claim 11, further comprising a filler material arranged in the gap.

13. A semiconductor device comprising:
a through-hole electrode substrate according to claim 1;
an LSI substrate connected to the through-hole electrode of the substrate; and
a semiconductor chip connected to the through-hole electrode of the substrate.

14. A manufacturing method of a through-hole electrode substrate using a substrate having a first surface, a second surface on an opposite side of the first surface and a through-hole passing through from the first surface to the second surface comprising:
forming a seed layer in the first surface side;
forming a first plating layer on the seed layer and covering the first open end; and
forming a second plating layer on the first plating layer from the first surface side towards the second surface side,
wherein a size of a first open end of the through-hole in the first surface side is smaller than a size of a second open end of the through-hole in the second surface side.
